(19) United States
(12) Patent Application Publication
(10) Pub. No.: US 2024/0310730 A1
(43) Pub. Date: Sep. 19, 2024

(54) RESIST UNDERLAYER FILM-FORMING COMPOSITION CONTAINING ACID CATALYST-SUPPORTING POLYMER

(71) Applicant: NISSAN CHEMICAL CORPORATION, Tokyo (JP)

(72) Inventors: Shou SHIMIZU, Toyama-shi (JP); Hiroyuki WAKAYAMA, Toyama-shi (JP); Mamoru TAMURA, Toyama-shi (JP)

(73) Assignee: NISSAN CHEMICAL CORPORATION, Tokyo (JP)

(21) Appl. No.: 18/281,833

(22) PCT Filed: Mar. 14, 2022
(86) PCT No.: PCT/JP2022/011190

§ 371 Date: Sep. 13, 2023

(30) Foreign Application Priority Data
Mar. 15, 2021 (JP) 2021-041584

(51) Int. Cl. G03F 7/11; C08G 59/12; C08G 59/14; H01L 21/027

(52) U.S. Cl. CPC G03F 7/11; C08G 59/12; C08G 59/1483; H01L 21/0274

(57) ABSTRACT

The present invention provides a composition for forming a resist underlayer film with which a desired resist pattern can be formed, a method for manufacturing a resist pattern wherein said resist underlayer film-forming composition is used, and a method for manufacturing a semiconductor device. The resist underlayer film-forming composition includes a polymer that supports an acid compound at a terminal end thereof, and a solvent. The acid compound may be ionically bonded to a base that is present at the terminal end of the polymer. Said terminal end may be represented by formula (1) (in the formula, A1 represents an acid compound, B represents a basic structure, and * represents a section of bonding with a polymer moiety).

### TECHNICAL FIELD

The present invention relates to a composition for use in a lithography process in manufacturing a semiconductor, in particular, in the state-of-the-art (ArF, EUV, EB, or the like) lithography process. In addition, the present invention relates to a method for manufacturing a substrate with a resist pattern to which the resist underlayer film is applied and a method for manufacturing a semiconductor device.

### BACKGROUND ART

Conventionally, in manufacturing of a semiconductor device, fine processing by lithography using a resist composition has been performed. The fine processing is a processing method for forming a thin film of a photoresist composition on a semiconductor substrate such as a silicon wafer, irradiating the thin film with active rays such as ultraviolet rays through a mask pattern in which a pattern of a device is formed, developing the thin film, and etching the substrate using the obtained photoresist pattern as a protective film, thereby forming fine unevenness corresponding to the pattern on a surface of the substrate. In recent years, a degree of integration of a semiconductor device has been increased, and in addition to an i-line (wavelength: 365 nm), a KrF excimer laser (wavelength: 248 nm), and an ArF excimer laser (wavelength: 193 nm) that have been used in the related art, active rays used for practical application of an extreme ultraviolet ray (EUV) (wavelength: 13.5 nm) or an electron beam (EB) have been studied for the state-of-the-art fine processing. Accordingly, there is a serious problem of resist pattern formation defects due to the influence of the semiconductor substrate and the like. Therefore, in order to solve this problem, a method of providing a resist underlayer film between the resist and the semiconductor substrate has been widely studied. Patent Literature 1 discloses a resist underlayer film-forming composition for EUV lithography containing a condensation polymer. Patent Literature 2 discloses a resist underlayer film-forming composition containing an alicyclic compound-terminated polymer.

### CITATION LIST

### Patent Literature

Patent Literature 1: WO 2013/018802 A
Patent Literature 2: WO 2020/226141 A

### SUMMARY OF INVENTION

### Technical Problem

The properties required for the resist underlayer film include, for example, that the film does not cause intermixing with a resist film formed on an upper layer (that is, the film is insoluble in a resist solvent), and that the film has a higher dry etching rate than that of the resist film.

In the case of lithography with EUV exposure, a line width of a resist pattern to be formed is 32 nm or less, and a resist underlayer film for EUV exposure is formed to be thinner than that in the related art. When such a thin film is formed, pinholes, agglomeration, and the like are likely to occur due to the influence of the surface of the substrate, the polymer to be used, and the like, and it is difficult to form a uniform film without defects.

On the other hand, when a resist pattern is formed, in a development process such as a negative development process in which an unexposed portion of a resist film is removed using a solvent that can dissolve the resist film, usually an organic solvent, and an exposed portion of the resist film is left as a resist pattern or a positive development process in which an exposed portion of the resist film is removed and an unexposed portion of the resist film is left as a resist pattern, improvement of adhesion of the resist pattern is a major problem.

An object of the present invention is to provide a composition for forming a resist underlayer film and a resist pattern forming method using the resist underlayer film-forming composition which have solved the above problems and can form a desired resist pattern.

### Solution to Problem

The present invention encompasses the followings.
[1]

A resist underlayer film-forming composition comprising and a solvent and a polymer that supports an acid compound at a terminal thereof.
[2]

The resist underlayer film-forming composition according to [1], wherein the acid compound is ionically bonded to a base present at a terminal of the polymer.
[3]

The resist underlayer film-forming composition according to [1] or [2], wherein
the terminal is represented by the following Formula (I):

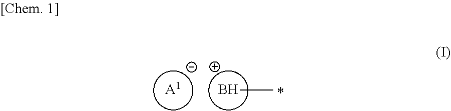

(in Formula (I), A¹ represents an acid compound, B represents a basic structure, and * is a binding site with a polymer residue).
[4]

The resist underlayer film-forming composition according to [3], wherein B contains a nitrogen atom.
[5]

The resist underlayer film-forming composition according to [3] or [4], wherein
B is R¹R²R³N,
R¹ and R² each independently represent an optionally substituted linear or branched saturated or unsaturated aliphatic hydrocarbon group,
R¹ and R² may form a ring with a heteroatom or without a heteroatom,
R³ represents an optionally substituted aromatic group, or an optionally substituted linear or branched saturated or unsaturated aliphatic hydrocarbon group, and
when R¹ and R² do not form a ring, R³ is an optionally substituted aromatic group.
[6]

The resist underlayer film-forming composition according to [3] or [4], wherein
B is a base represented by

R¹R²R³N [Chem. 2]

[in the formula,
R¹ and R² each independently represent an optionally substituted linear or branched saturated or unsaturated aliphatic hydrocarbon group, and
R³ represents an optionally substituted aromatic group], or
the following Formula (II):

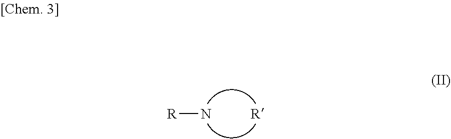

### [in Formula (II),

R is a hydrogen atom, a nitro group, a cyano group, an amino group, a carboxyl group, a halogen atom, an alkoxy group having 1 to 10 carbon atoms, an alkyl group having 1 to 10 carbon atoms, an alkenyl group having 2 to 10 carbon atoms, an aryl group having 6 to 40 carbon atoms, an organic group containing an ether bond, an organic group containing a ketone bond, an organic group containing an ester bond, or a combination thereof,
R′ is

—(R^{a})ₙ—X—(R^{b})ₘ— [Chem. 4]
R^{a} and R^{b} each independently represent an optionally substituted alkyl,
X is O, S, or SO₂, and
n and m are each independently 2, 3, 4, 5, or 6].
[7]

The resist underlayer film-forming composition according to [6], wherein
R³ represents an optionally substituted phenyl, naphthyl, anthracenyl, or phenanthrenyl group,
R is a hydrogen atom, a methyl group, an ethyl group, an allyl group, or a cyanomethyl group, and
R′ is a base represented by

—(CH₂)ₙ—O—(CH₂)ₘ— [Chem. 5]
[8]

The resist underlayer film-forming composition according to any one of [3] to [7], in which
A¹ is represented by the following formula:

[Chem. 6]

(A-SO₃) (I I I)

(in Formula (III), A is an optionally substituted linear, branched, or cyclic saturated or unsaturated aliphatic hydrocarbon group, an aryl group which may be substituted with a group other than a carboxyl group, or an optionally substituted heteroaryl group).
[9]

The resist underlayer film-forming composition according to any one of [1] to [8], in which
the polymer is a polymer having a repeating unit structure represented by the following Formula (1):

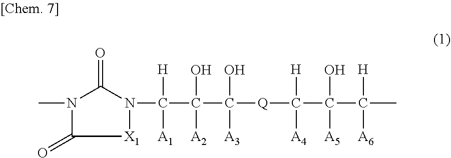

[in the formula, each of A₁, A₂, A₃, A₄, A₅, and A₆ represents a hydrogen atom, a methyl group, or an ethyl group, X₁ represents Formula (2), Formula (3), Formula (4), or Formula (0):

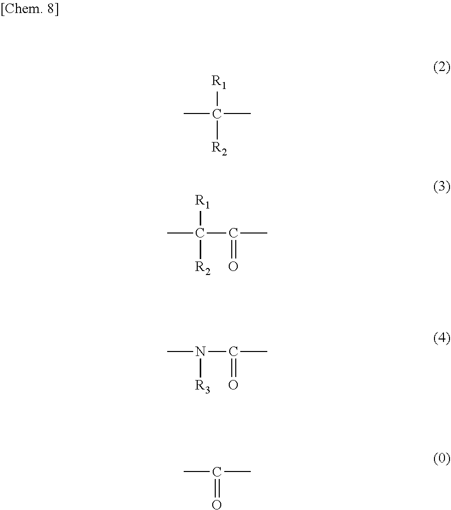

(in the formula, each of R₁ and R₂ represents a hydrogen atom, a halogen atom, an alkyl group having 1 to 6 carbon atoms, an alkenyl group having 3 to 6 carbon atoms, a benzyl group, or a phenyl group, in which the alkyl group having 1 to 6 carbon atoms, the alkenyl group having 3 to 6 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 6 carbon atoms, R₁ and R₂ may be bonded to each other to form a ring having 3 to 6 carbon atoms, and R₃ represents a halogen atom, an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms), and Q represents Formula (5) or Formula (6):

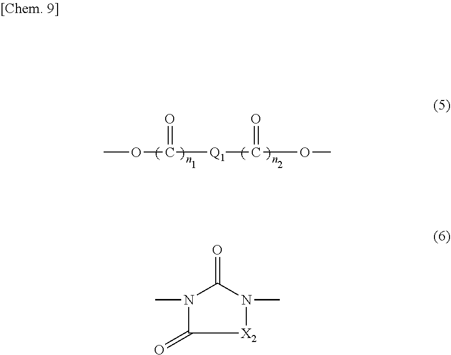

(in the formula, Q₁ represents an alkylene group having 1 to 10 carbon atoms, a phenylene group, a naphthylene group, or an anthrylene group, in which each of the alkylene group, the phenylene group, the naphthylene group, and the anthrylene group may be substituted with an alkyl group having 1 to 6 carbon atoms, a carbonyloxyalkyl group having 2 to 7 carbon atoms, a halogen atom, an alkoxy group having 1 to 6 carbon atoms, a phenyl group, a nitro group, a cyano group, a hydroxy group, an alkylthio group having 1 to 6 carbon atoms, a group having a disulfide group, a carboxyl group, or a combination thereof, and the alkylene group may be interrupted by a disulfide bond, each of n₁ and n₂ represents a number of 0 or 1, and X₂ represents Formula (2), Formula (3), or Formula (0))].
[10]

The resist underlayer film-forming composition according to any one of [1] to [9], further comprising a crosslinking agent.
[11]

The resist underlayer film-forming composition according to any one of [1] to [10], further comprising an acid generator.
[12]

A resist underlayer film which is a baked product of a coating film formed of the resist underlayer film-forming composition according to [1] to [11].
[13]

A method for manufacturing a patterned substrate, the method comprising:
applying the resist underlayer film-forming composition according to any one of [1] to [11] onto a semiconductor substrate and baking the resist underlayer film-forming composition to form a resist underlayer film;
applying a resist onto the resist underlayer film and baking the resist to form a resist film;
exposing the semiconductor substrate coated with the resist underlayer film and the resist; and
developing the exposed resist film and performing patterning.
[14]

A method for manufacturing a semiconductor device, the method including:
forming a resist underlayer film formed of the resist underlayer film-forming composition according to any one of [1] to [11] on a semiconductor substrate;
forming a resist film on the resist underlayer film;
forming a resist pattern by irradiating the resist film with a light or electron beam and then developing the resist film;
forming a patterned resist underlayer film by etching the resist underlayer film through the formed resist pattern; and
processing the semiconductor substrate by the patterned resist underlayer film.

### Advantageous Effects of Invention

The resist underlayer film-forming composition of the present invention has excellent applicability on a semiconductor substrate to be processed and provides excellent adhesion at an interface between a resist and a resist underlayer film when a resist pattern is formed, such that an excellent resist pattern having a rectangular shape can be formed without causing peeling or collapsing of the resist pattern. In particular, a remarkable effect is exhibited when EUV (wavelength: 13.5 nm) or electron beam (EB) is used.

### DESCRIPTION OF EMBODIMENTS

### <Resist Underlayer Film-Forming Composition>

A resist underlayer film-forming composition of the present invention contains a solvent and a polymer that supports an acid compound at a terminal thereof.

### <Acid Compound>

The acid compound of the present invention is not limited as long as it is an acid compound exhibiting the advantageous effects of the present invention, and both a thermal acid generator and a photoacid generator may be used. Examples of the thermal acid generator include sulfonic acid compounds such as p-toluenesulfonic acid, trifluoromethanesulfonic acid, pyridinium p-toluenesulfonate (pyridinium p-toluenesulfonic acid), pyridinium phenolsulfonic acid, pyridinium p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid, and carboxylic acid compounds.

Examples of the photoacid generator include an onium salt compound, a sulfonimide compound, and a disulfonyl diazomethane compound.

Examples of the onium salt compound include iodonium salt compounds such as diphenyliodoniumhexafluorophosphate, diphenyliodoniumtrifluoromethanesulfonate, diphenyliodoniumnonafluoro n-butane sulfonate, diphenyliodoniumperfluoro n-octane sulfonate, diphenyliodoniumcamphorsulfonate, bis(4-tert-butylphenyl)iodoniumcamphorsulfonate, and bis(4-tert-butylphenyl)iodoniumtrifluoromethanesulfonate; and sulfonium salt compounds such as triphenylsulfoniumhexafluoroantimonate, triphenylsulfoniumnonafluoro n-butane sulfonate, triphenylsulfoniumcamphorsulfonate, and triphenylsulfoniumtrifluoromethanesulfonate.

Examples of the sulfonimide compound include N-(trifluoromethanesulfonyloxy)succinimide, N-(nonafluoro n-butanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

As the acid compound, only one species of an acid generator may be used, or two or more species of acid generators may be used in combination.

A method for supporting the acid compound on the polymer is not limited, and as in the method described in Examples, the acid compound may be supported by adding the acid compound to a solution of a polymer having a structure capable of supporting an acid at a terminal thereof and stirring the resultant mixture. The proportion (% by mole) of the acid compound supported at the terminal of the polymer can be indirectly calculated from the amount of the acid compound removed at the time of polymer purification by the preparation method described in Examples. It is, for example, 50% by mole or more, 70% by mole or more, or 90% by mole or more. And it is preferable that the acid compound is supported at the terminal of the polymer in an amount of 98% by mole or more.

The acid compound also has a role of promoting a crosslinking reaction between the polymer and a crosslinking agent described below.

The acid compound may be ionically bonded to a base present at a terminal of the polymer.

The terminal may be represented by the following Formula (I):

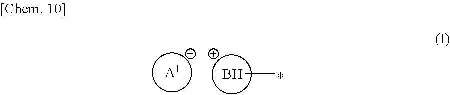

(in Formula (I), A¹ represents an acid compound, B represents a basic structure, and * is a binding site with a polymer residue).

B may contain a nitrogen atom.
B may be R¹R²R³N,
R¹ and R² may each independently represent an optionally substituted linear or branched saturated or unsaturated aliphatic hydrocarbon group,
R¹ and R² may form a ring with a heteroatom or without a heteroatom,
R³ may represent an optionally substituted aromatic group, or an optionally substituted linear or branched saturated or unsaturated aliphatic hydrocarbon group, and
when R¹ and R² do not form a ring, R³ may be an optionally substituted aromatic group.

B may be a base represented by

R¹R²R³N [Chem. 11]

[in the formula,
R¹ and R² each independently represent an optionally substituted linear or branched saturated or unsaturated aliphatic hydrocarbon group, and
R³ represents an optionally substituted aromatic group], or
the following Formula (II):

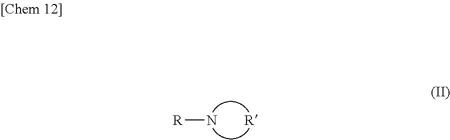

### [in Formula (II),

R is a hydrogen atom, a nitro group, a cyano group, an amino group, a carboxyl group, a halogen atom, an alkoxy group having 1 to 10 carbon atoms, an alkyl group having 1 to 10 carbon atoms, an alkenyl group having 2 to 10 carbon atoms, an aryl group having 6 to 40 carbon atoms, an organic group containing an ether bond, an organic group containing a ketone bond, an organic group containing an ester bond, or a combination thereof,
R′ is

—(R^{a})ₙ—X—(R^{b})ₘ—, [Chem. 13]
R^{a} and R^{b} each independently represent an optionally substituted alkyl,
X is O, S, or SO₂, and
n and m are each independently 2, 3, 4, 5, or 6].

R³ may represent an optionally substituted phenyl, naphthyl, anthracenyl, or phenanthrenyl group,
R may be a hydrogen atom, a methyl group, an ethyl group, an allyl group, or a cyanomethyl group, and
R′ may be a base represented by

—(CH₂)ₙ—O—(CH₂)ₘ—. [Chem. 14]

A¹ may be represented by the following formula:

[Chem. 15]

(A-SO₃)⁻ (I I I)

(in Formula (III), A is an optionally substituted linear, branched, or cyclic saturated or unsaturated aliphatic hydrocarbon group, an aryl group which may be substituted with a group other than a carboxyl group, or an optionally substituted heteroaryl group).

Examples of the linear, branched, or cyclic saturated aliphatic hydrocarbon group include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

Examples of a linear, branched, or cyclic unsaturated aliphatic hydrocarbon group include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group.

Examples of the aryl group include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the heteroaryl group include a furanyl group, a thiophenyl group, a pyrrolyl group, an imidazolyl group, a pyranyl group, a pyridinyl group, a pyrimidinyl group, a pyrazinyl group, a pyrrolidinyl group, a piperidinyl group, a piperazinyl group, a morpholinyl group, a quinuclidinyl group, an indolyl group, a purinyl group, a quinolinyl group, an isoquinolinyl group, a chromenyl group, a thianthrenyl group, a phenothiazinyl group, a phenoxazinyl group, a xanthenyl group, an acridinyl group, a phenazinyl group, and a carbazolyl group.

The aryl group and the heteroaryl group are encompassed by an aromatic group.

Examples of the substituent include a nitro group, an amino group, a cyano group, a sulfo group, a hydroxy group, a carboxyl group, a halogen atom, an alkoxy group having 1 to 10 carbon atoms, an alkyl group having 1 to 10 carbon atoms, an alkenyl group having 2 to 10 carbon atoms, an aryl group having 6 to 40 carbon atoms, an organic group containing an ether bond, an organic group containing a ketone bond, an organic group containing an ester bond, and a combination thereof.

Examples of the halogen atom include a fluorine atom, a chlorine atom, a bromine atom, and an iodine atom.

Examples of the alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

The alkyl group, the alkenyl group, and the aryl group are as exemplified above.

The organic group containing an ether bond may be represented by R¹¹—O—R¹¹ (R¹¹'s each independently represent an alkyl group having 1 to 6 carbon atoms such as a methyl group or an ethyl group, an alkylene group, a phenyl group, or a phenylene group), and examples thereof include organic groups containing an ether bond, including a methoxy group, an ethoxy group, and a phenoxy group.

The organic group containing a ketone bond may be represented by R²¹—C(═O)—R²¹ (R²¹'s each independently represent an alkyl group having 1 to 6 carbon atoms such as a methyl group or an ethyl group, an alkylene group, a phenyl group, or a phenylene group), and examples thereof include organic groups containing a ketone bond, including an acetoxy group and a benzoyl group.

The organic group containing an ester bond may be represented by R³¹—C(═O)O—R³¹ (R³¹'s each independently represent an alkyl group having 1 to 6 carbon atoms such as a methyl group or an ethyl group, an alkylene group, a phenyl group, or a phenylene group), and examples thereof include organic groups containing an ester bond such as a methyl ester, an ethyl ester, or a phenyl ester.

Note that A excludes an aryl group substituted with a hydroxy group. Therefore, an anion derived from p-phenol sulfonic acid, o-cresol-4-sulfonic acid, p-cresol-2-sulfonic acid, or the like is excluded from (A-SO₃)⁻ in the present invention. In addition, preferably, A excludes an aryl group substituted with a carboxyl group. Therefore, an anion derived from 5-sulfosalicylic acid or the like is excluded from (A-SO₃)⁻ in the present invention.

Preferably, A is a methyl group, a fluoromethyl group, or a tolyl group.

In the present invention, specific examples of B include N-methylmorpholine and N,N-diethylaniline.

### <Polymer>

The polymer contained in the resist underlayer film-forming composition of the present invention is not limited as long as it is a polymer that exhibits the advantageous effects of the present application, and may be a polymer having a repeating unit structure represented by Formula (1) described in WO 2013/018802 A:

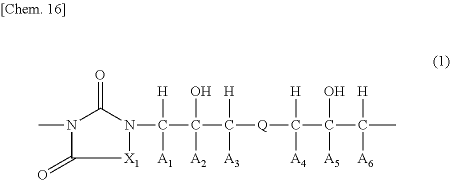

[in the formula, each of A₁, A₂, A₃, A₄, A₅, and A₆ represents a hydrogen atom, a methyl group, or an ethyl group, X₁ represents Formula (2), Formula (3), Formula (4), or Formula (0):

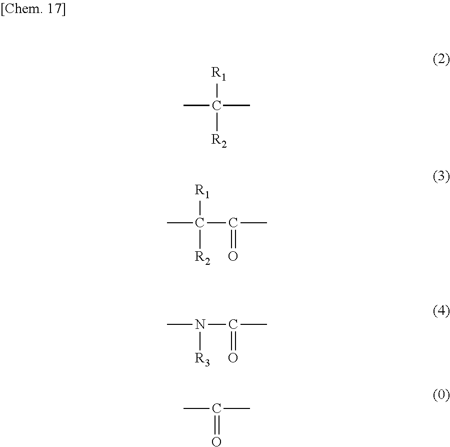

(in the formula, each of R₁ and R₂ represents a hydrogen atom, a halogen atom, an alkyl group having 1 to 6 carbon atoms, an alkenyl group having 3 to 6 carbon atoms, a benzyl group, or a phenyl group, in which the alkyl group having 1 to 6 carbon atoms, the alkenyl group having 3 to 6 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 6 carbon atoms, R₁ and R₂ may be bonded to each other to form a ring having 3 to 6 carbon atoms, and R₃ represents a halogen atom, an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms), and Q represents Formula (5) or Formula (6):

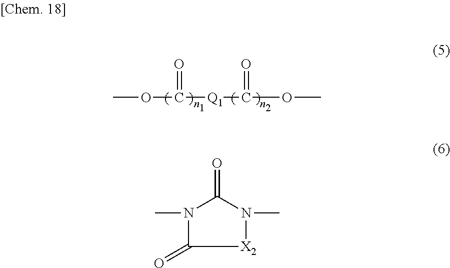

(in the formula, Q₁ represents an alkylene group having 1 to 10 carbon atoms, a phenylene group, a naphthylene group, or an anthrylene group, in which each of the alkylene group, the phenylene group, the naphthylene group, and the anthrylene group may be substituted with an alkyl group having 1 to 6 carbon atoms, a carbonyloxyalkyl group having 2 to 7 carbon atoms, a halogen atom, an alkoxy group having 1 to 6 carbon atoms, a phenyl group, a nitro group, a cyano group, a hydroxy group, an alkylthio group having 1 to 6 carbon atoms, a group having a disulfide group, a carboxyl group, or a combination thereof, and the alkylene group may be interrupted by a disulfide bond, each of n₁ and n₂ represents a number of 0 or 1, and X₂ represents Formula (2), Formula (3), or Formula (0))].

Specific examples of the alkyl group include a methyl group, an ethyl group, a propyl group, an isopropyl group, a normal butyl group, and a cyclohexyl group. Specific examples of the alkenyl group include a 2-propenyl group and a 3-butenyl group. In addition, R₁ and R₂ may be bonded to each other to form a ring having 3 to 6 carbon atoms, and examples of such a ring include a cyclobutane ring, a cyclopentane ring, and a cyclohexane ring.

Examples of the alkoxy group include a methoxy group, an ethoxy group, a propoxy group, and an isopropoxy group.

Examples of the group having a disulfide group include a —S—S—R group and a —R—S—S—R group. Here, R represents the alkyl group, the alkylene group, the aryl group, or the arylene group described above.

Specific examples of the repeating unit structure represented by Formula (1) include repeating unit structures of Formula (13) to Formula (32).

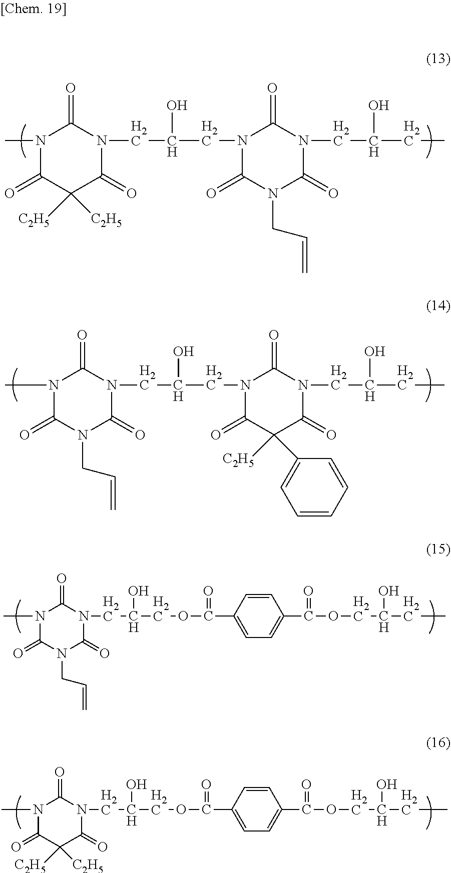

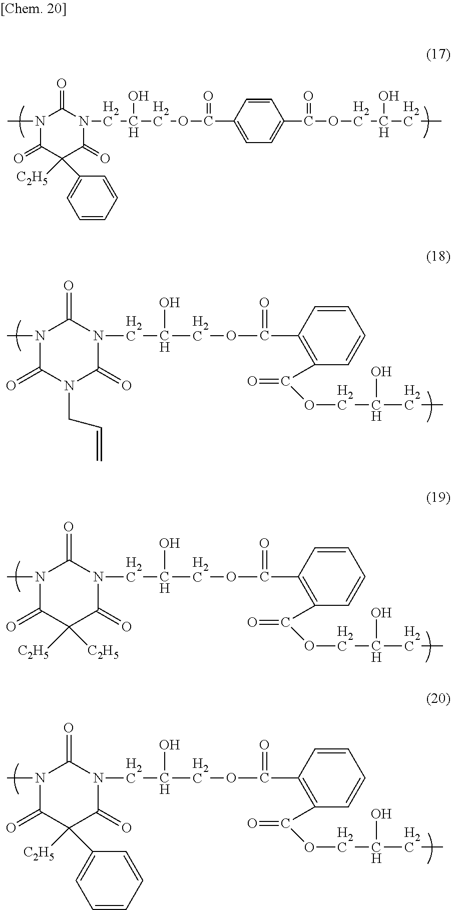

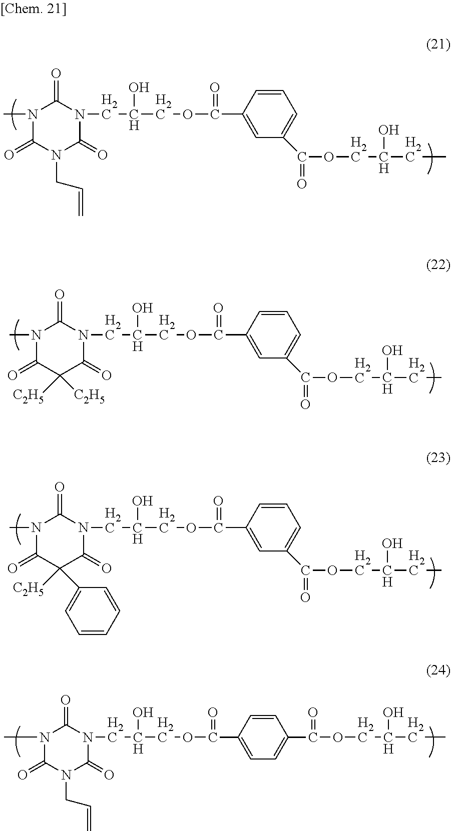

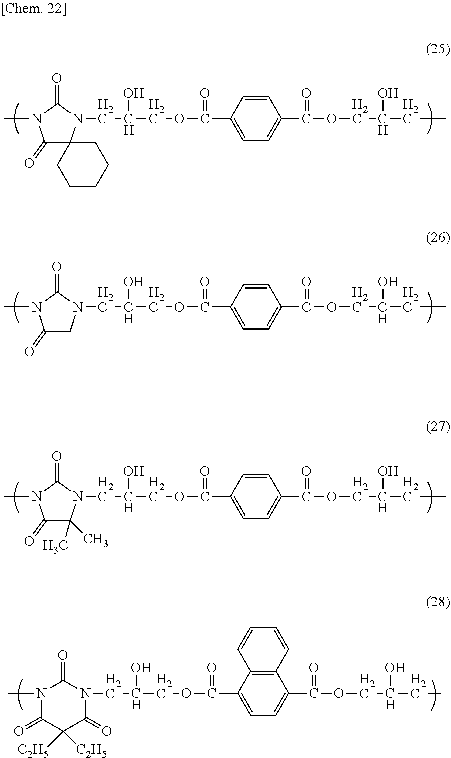

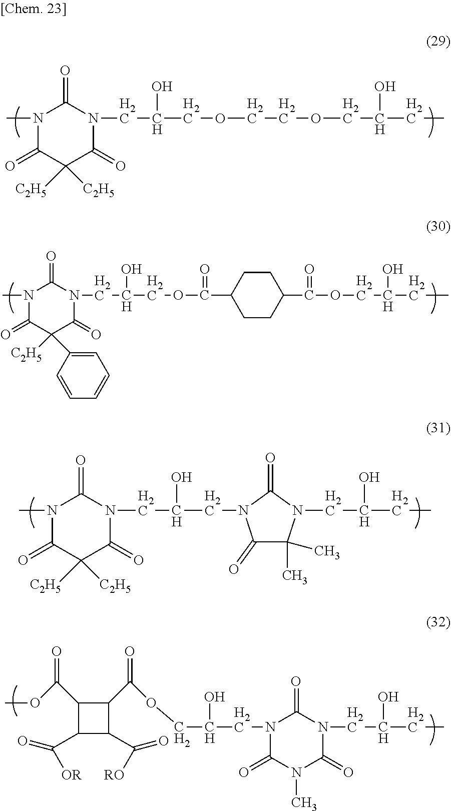

In Formula (32), R is an alcohol residue (an organic group other than a hydroxy group of an alcohol), and R represents an alkyl group, an ether group, or a combination thereof. Examples of R include an alkyl group and an alkoxyalkyl group. Examples of the alkyl group and the alkoxy group include the examples described above.

The entire disclosure of WO 2013/018802 A is incorporated in the present description by reference.

The lower limit of a weight average molecular weight of the polymer is, for example, 500, 1,000, 2,000, or 3,000, and the upper limit of a weight average molecular weight of the reaction product is, for example, 30,000, 20,000, or 10,000.

### <Solvent>

The solvent to be used in the resist underlayer film-forming composition of the present application is not particularly limited as long as it is a solvent that can uniformly dissolve a solid-containing component such as the polymer at room temperature, and an organic solvent generally used in a chemical solution for a semiconductor lithography process is preferable. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propropylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. These solvents may be used each alone or in combination of two or more thereof.

Of these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Acid Generator>

The acid generator contained as an optional component in the resist underlayer film-forming composition of the present invention may further contain the same or different acid compound and acid generator in addition to the acid compound supported at a terminal of the polymer. As the acid generator, a thermal acid generator and a photoacid generator may be used, but it is preferable to use a thermal acid generator. Examples of the thermal acid generator include sulfonic acid compounds such as p-toluenesulfonic acid, trifluoromethanesulfonic acid, pyridinium p-toluenesulfonate (pyridinium p-toluenesulfonic acid), pyridinium phenolsulfonic acid, pyridinium p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid, and carboxylic acid compounds.

Examples of the photoacid generator include an onium salt compound, a sulfonimide compound, and a disulfonyl diazomethane compound.

Examples of the onium salt compound include iodonium salt compounds such as diphenyliodoniumhexafluorophosphate, diphenyliodoniumtrifluoromethanesulfonate, diphenyliodoniumnonafluoro n-butane sulfonate, diphenyliodoniumperfluoro n-octane sulfonate, diphenyliodoniumcamphorsulfonate, bis(4-tert-butylphenyl)iodoniumcamphorsulfonate, and bis(4-tert-butylphenyl)iodoniumtrifluoromethanesulfonate; and sulfonium salt compounds such as triphenylsulfoniumhexafluoroantimonate, triphenylsulfoniumnonafluoro n-butane sulfonate, triphenylsulfoniumcamphorsulfonate, and triphenylsulfoniumtrifluoromethanesulfonate.

Examples of the sulfonimide compound include N-(trifluoromethanesulfonyloxy)succinimide, N-(nonafluoro n-butanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

As the acid generator, only one species of an acid generator may be used, or two or more species of acid generators may be used in combination.

In a case where an acid generator is used, the content ratio of the acid generator is, for example, 0.1% by mass to 50% by mass, and preferably, 1% by mass to 30% by mass, relative to the following crosslinking agent.

In a case where an acid generator is used, the content ratio of the acid generator is within the range of 50 to 200% by mole or 80 to 150% by mole relative to the terminal of the polymer.

### <Crosslinking Agent>

Examples of a crosslinking agent contained as an optional component in the resist underlayer film-forming composition of the present invention include hexamethoxymethylmelamine, tetramethoxymethyl benzoguanamine, 1,3,4,6-tetrakis(methoxymethyl)glycoluril (tetramethoxymethyl glycoluril) (POWDERLINK [registered trademark] 1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

In addition, the crosslinking agent of the present application may be a nitrogen-containing compound having 2 to 6 substituents represented by the following Formula (1d) bonded to a nitrogen atom per molecule, which is described in WO 2017/187969 A.

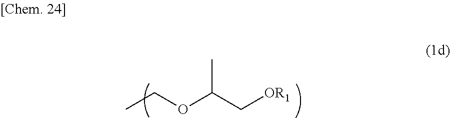

(In Formula (1d), R₁ represents a methyl group or an ethyl group.)

The nitrogen-containing compound having 2 to 6 substituents represented by Formula (1d) per molecule may be a glycoluril derivative represented by the following Formula (1E).

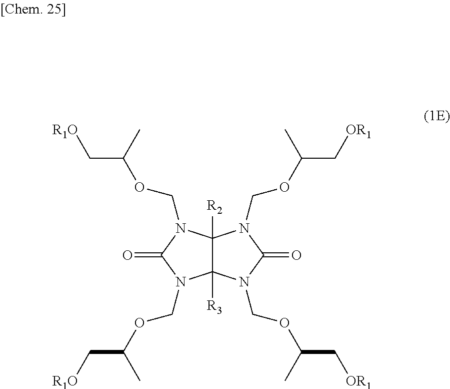

(In Formula (1E), four R₁'s each independently represent a methyl group or an ethyl group, and R₂ and R₃ each independently represent a hydrogen atom, an alkyl group having 1 to 4 carbon atoms, or a phenyl group.)

Examples of the glycoluril derivative represented by Formula (1E) include compounds represented by the following Formula (1E-1) to Formula (1E-6).

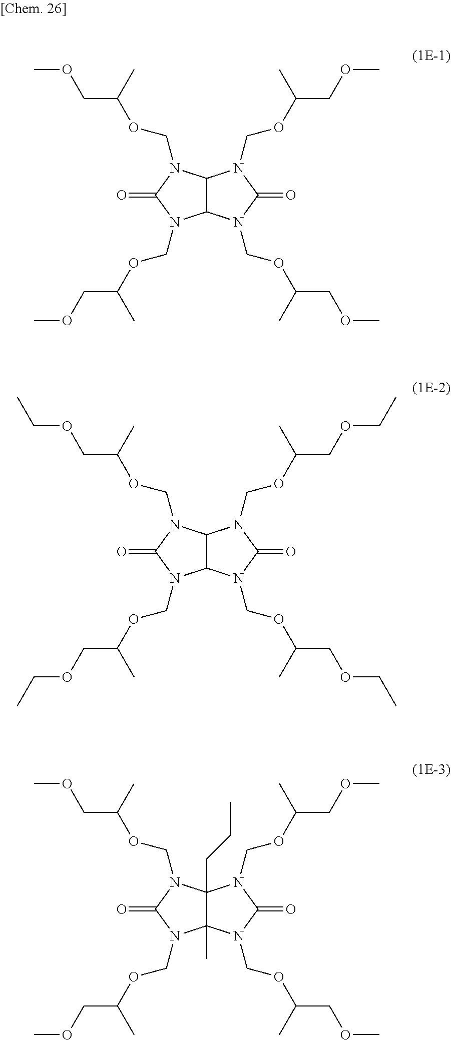

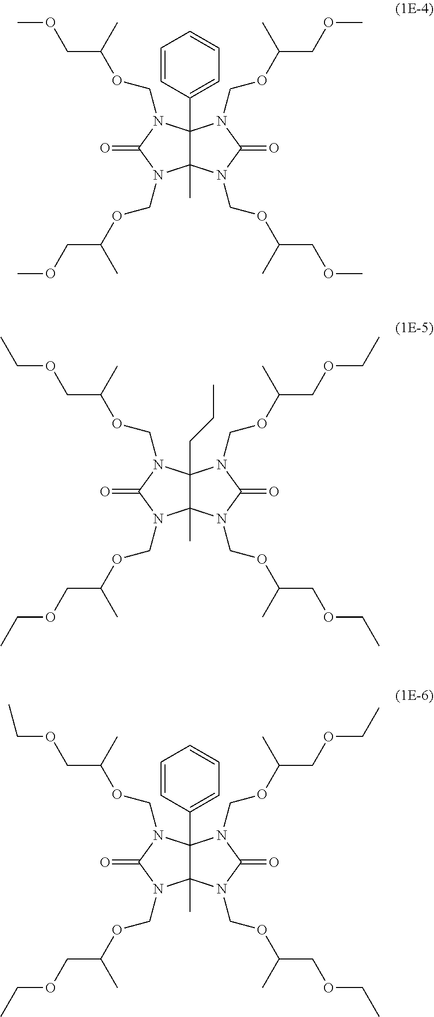

The nitrogen-containing compound having 2 to 6 substituents represented by Formula (1d) per molecule is obtained by reacting a nitrogen-containing compound having 2 to 6 substituents bonded to a nitrogen atom and represented by the following Formula (2d) per molecule with at least one compound represented by the following Formula (3d).

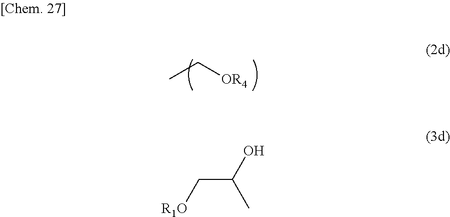

(In Formula (2d) and Formula (3d), R₁ represents a methyl group or an ethyl group and R₄ represents an alkyl group having 1 to 4 carbon atoms.)

The glycoluril derivative represented by Formula (1E) is obtained by reacting a glycoluril derivative represented by the following Formula (2E) with at least one compound represented by Formula (3d).

The nitrogen-containing compound having 2 to 6 substituents represented by Formula (2d) per molecule is, for example, a glycoluril derivative represented by the following Formula (2E).

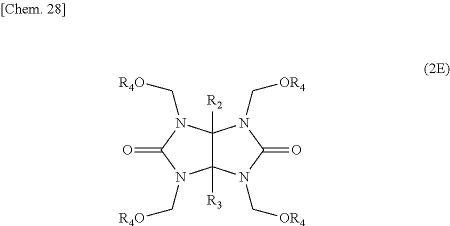

(In Formula (2E), R₂ and R₃ each independently represent a hydrogen atom, an alkyl group having 1 to 4 carbon atoms, or a phenyl group, and R₄'s each independently represent an alkyl group having 1 to 4 carbon atoms.)

Examples of the glycoluril derivative represented by Formula (2E) include compounds represented by the following Formula (2E-1) to Formula (2E-4). Further, examples of the compound represented by Formula (3d) include compounds represented by the following Formula (3d-1) and Formula (3d-2).

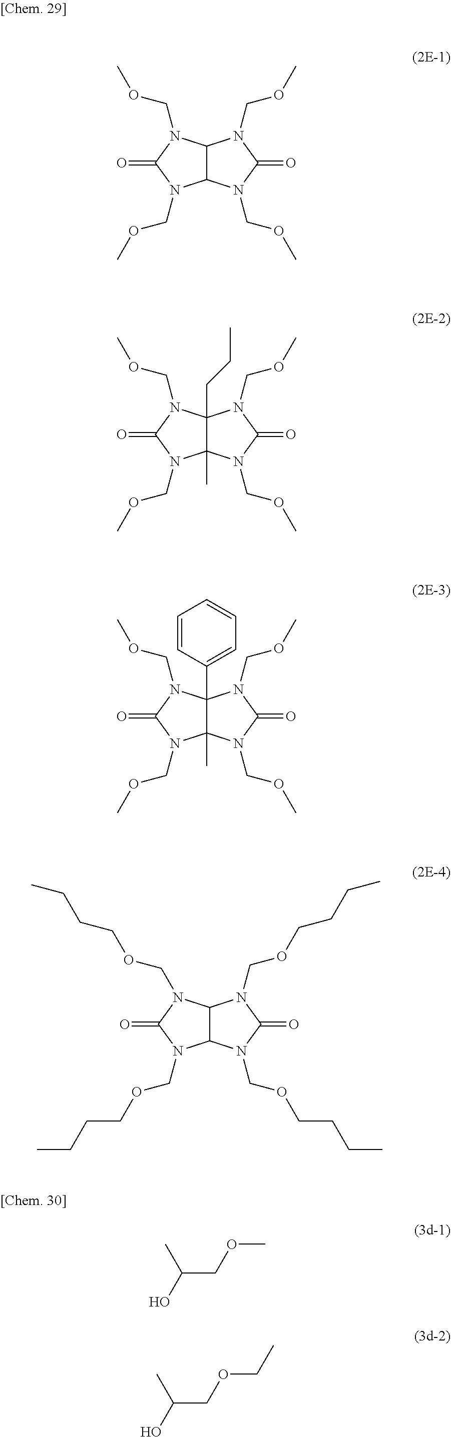

For the contents related to the nitrogen-containing compound having 2 to 6 substituents bonded to a nitrogen atom and represented by the following Formula (1d) per molecule, the entire disclosure of WO 2017/187969 A is incorporated in the present description by reference.

In addition, the crosslinking agent may be a crosslinkable compound represented by the following Formula (G-1) or Formula (G-2) described in WO 2014/208542 A.

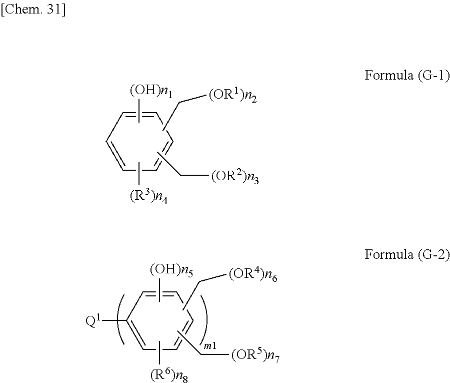

(In the formula, Q¹ represents a single bond or an m1-valent organic group, R¹ and R⁴ each represent an alkyl group having 2 to 10 carbon atoms or an alkyl group having 2 to 10 carbon atoms which has an alkoxy group having 1 to 10 carbon atoms, R² and R⁵ each represent a hydrogen atom or a methyl group, and R³ and R⁶ each represent an alkyl group having 1 to 10 carbon atoms or an aryl group having 6 to 40 carbon atoms.
n1 represents an integer that meets 1≤n1≤3; n2 represents an integer that meets 2≤n2≤5; n3 represents an integer that meets 0≤n3≤3; and n4 represents an integer that meets 0≤n4≤3 or an integer that meets 3≤(n1+n2+n3+n4)≤6.
n5 represents an integer that meets 1≤n5≤3; n6 represents an integer that meets 1≤n6≤4; n7 represents an integer that meets 0≤n7≤3; and n8 represents an integer that meets 0≤n8≤3 or an integer that meets 2≤(n5+n6+n7+n8)≤5.
m1 represents an integer of 2 to 10.)

The crosslinkable compound represented by Formula (G-1) or Formula (G-2) may be obtained by a reaction of a compound represented by the following Formula (G-3) or Formula (G-4) with a hydroxyl group-containing ether compound or an alcohol having 2 to 10 carbon atoms.

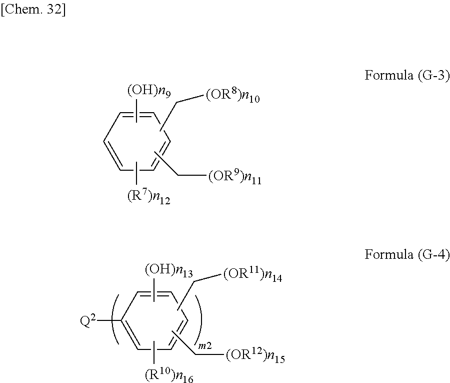

(In the formula, Q² represents a single bond or an m2-valent organic group, R⁸, R⁹, R¹¹, and R¹² each represent a hydrogen atom or a methyl group, and R⁷ and R¹⁰ each represent an alkyl group having 1 to 10 carbon atoms or an aryl group having 6 to 40 carbon atoms.
n9 represents an integer that meets 1≤n9≤3; n10 represents an integer that meets 2≤n10≤5; n11 represents an integer that meets 0≤n11≤3; and n12 represents an integer that meets 0≤n12≤3 or an integer that meets 3≤(n9+n10+n11+n12)≤6.
n13 represents an integer that meets 1≤n13≤3; n14 represents an integer that meets 1≤n14≤4; n15 represents an integer that meets 0≤n15≤3; and n16 represents an integer that meets 0≤n16≤3 or an integer that meets 2≤(n13+n14+n15+n16)≤5.
m2 represents an integer of 2 to 10.)

The compounds represented by Formula (G-1) and Formula (G-2) may be exemplified below.

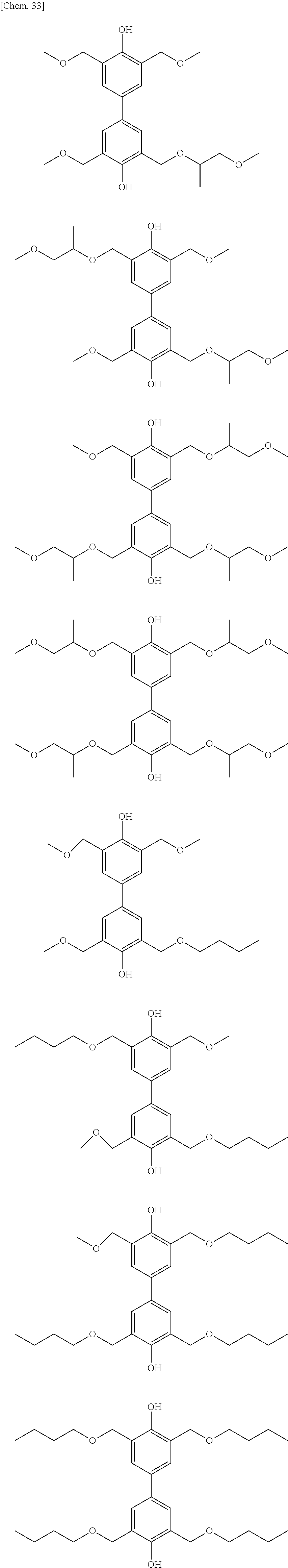

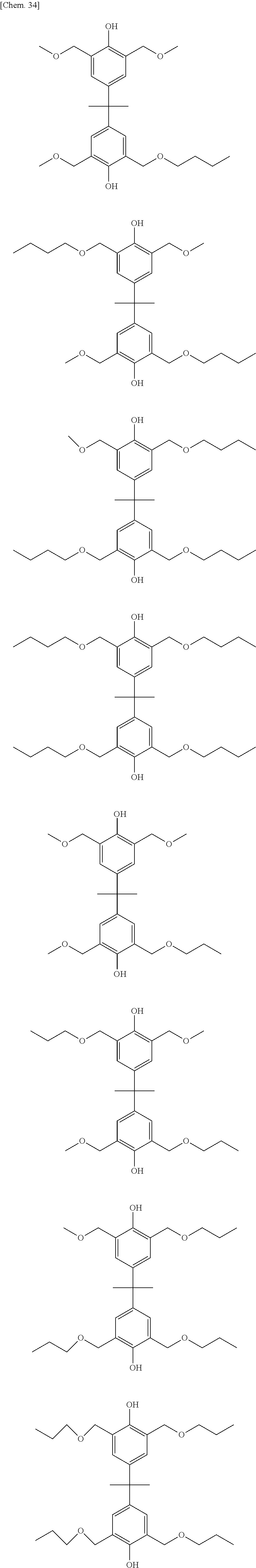

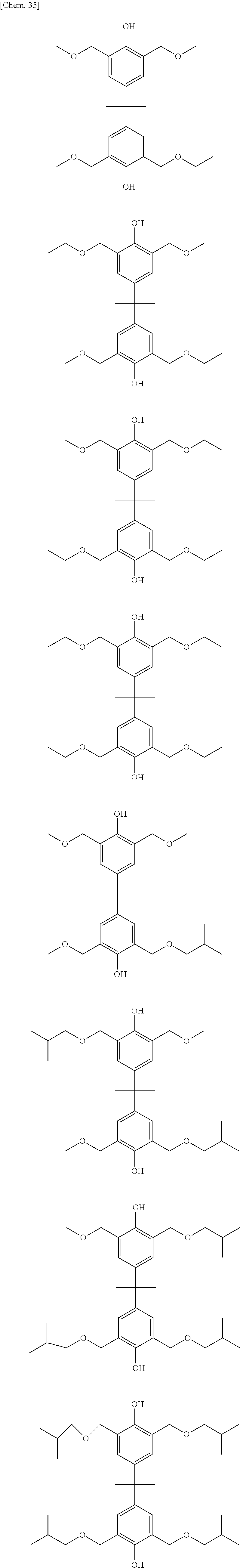

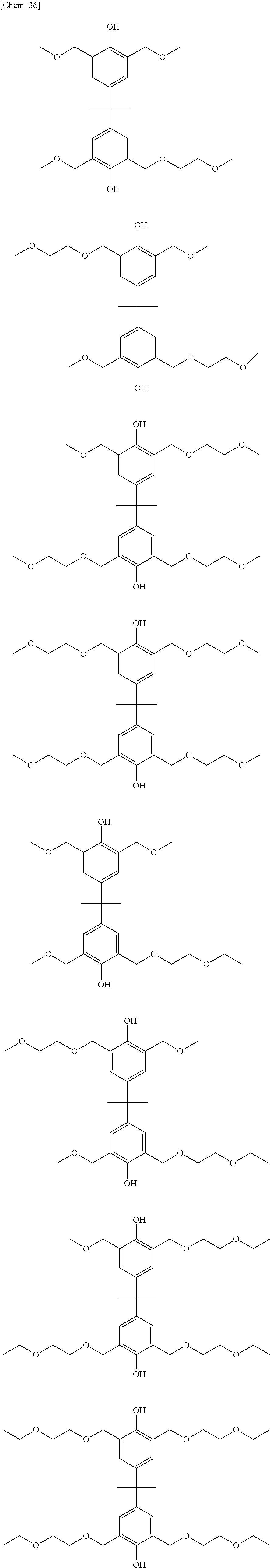

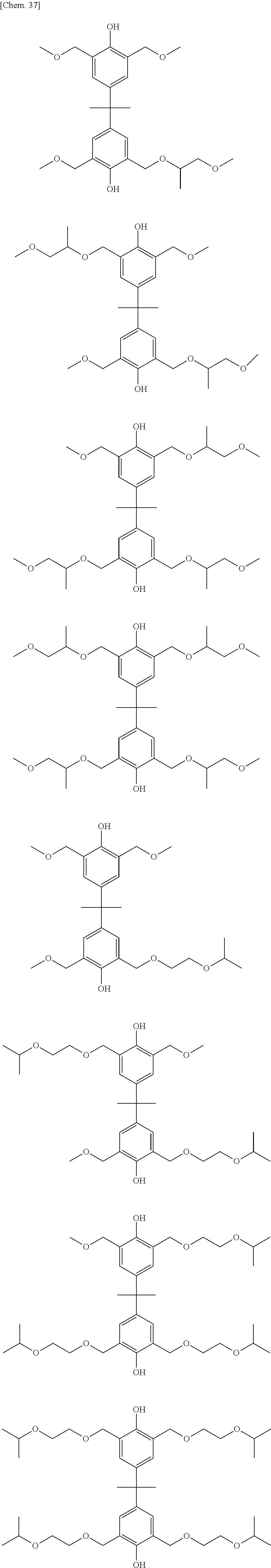

The compounds represented by Formula (G-3) and Formula (G-4) may be exemplified below.

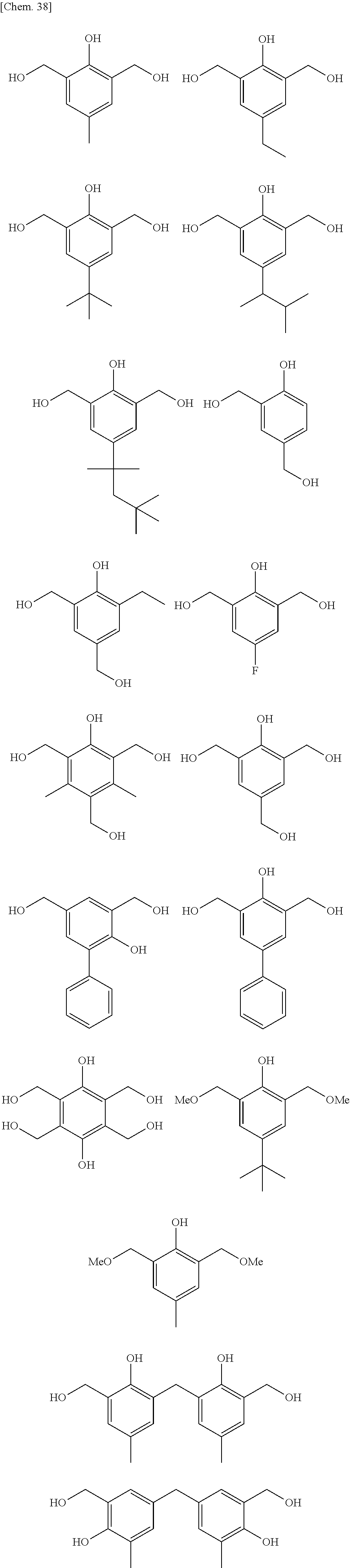

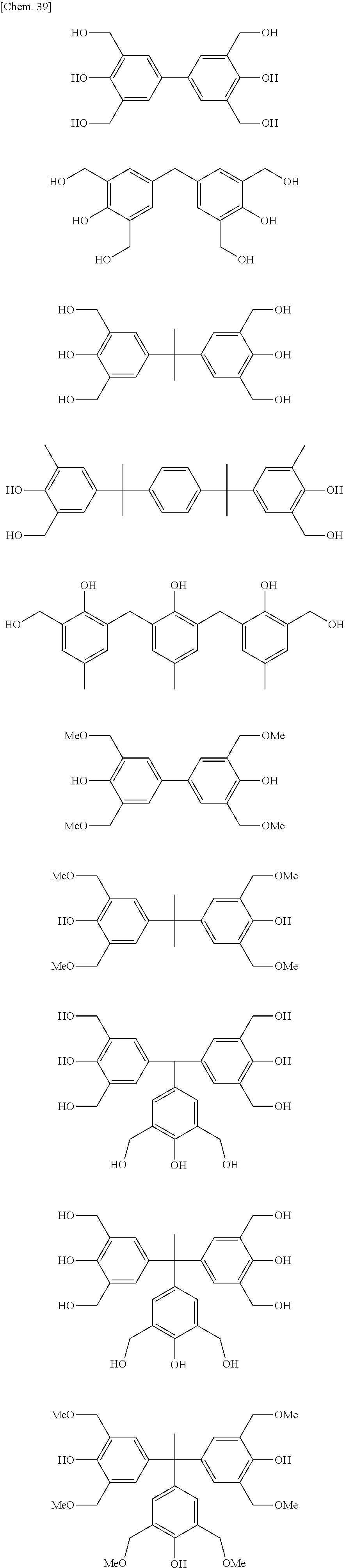

In the formula, Me represents a methyl group.

The entire disclosure of WO 2014/208542 A is incorporated in the present description by reference.

In a case where a crosslinking agent is used, the content ratio of the crosslinking agent is, for example, within the range of 1% by mass to 50% by mass, and preferably, 5% by mass to 30% by mass, relative to the reaction product.

### <Other Components>

In the resist underlayer film-forming composition of the present invention, there is no occurrence of pinholes, striations, or the like, and a surfactant may be further added in order to further improve the applicability for surface unevenness. Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP EF301, EF303, and EF352 (manufactured by Tochem Products Co. Ltd., trade name), Megafac F171, F173, and R-30 (manufactured by Dainippon Ink Co., Ltd., trade name), Fluorad FC430 and FC431 (manufactured by Sumitomo 3M Limited, trade name), and AsahiGuard AG710 and Surflon S-382, SC101, SC102, SC103, SC104, SC105, and SC106 (manufactured by AGC Inc.), and Organosiloxane polymer KP341 (manufactured by Shin-Etsu Chemical Co., Ltd.). The blending amount of these surfactants is usually 2.0% by mass or less, and preferably 1.0% by mass or less, relative to the total solid content of the resist underlayer film-forming composition of the present invention. These surfactants may be added each alone or in combination of two or more thereof.

The solid content contained in the resist underlayer film-forming composition of the present invention, that is, the component excluding the solvent is, for example, within the range of 0.01% by mass to 10% by mass.

### <Resist Underlayer Film>

The resist underlayer film according to the present invention may be manufactured by applying the resist underlayer film-forming composition described above onto a semiconductor substrate and performing baking.

Examples of the semiconductor substrate on which the resist underlayer film-forming composition of the present invention is applied include a silicon wafer, a germanium wafer, and a semiconductor wafer formed of a compound such as gallium arsenide, indium phosphide, gallium nitride, indium nitride, or aluminum nitride.

In a case where a semiconductor substrate having a surface on which an inorganic film is formed is used, the inorganic film is formed by, for example, an atomic layer deposition (ALD) method, a chemical vapor deposition (CVD) method, a reactive sputtering method, an ion-plating method, a vacuum deposition method, or a spin coating method (spin on glass: SOG). Examples of the inorganic film include a polysilicon film, a silicon oxide film, a silicon nitride film, a Boro-Phospho Silicate Glass (BPSG) film, a titanium nitride film, a titanium nitride oxide film, a tungsten film, a gallium nitride film, and a gallium arsenide film.

The resist underlayer film-forming composition of the present invention is applied onto the semiconductor substrate by an appropriate application method such as a spinner or a coater. Thereafter, baking is performed using heating means such as a hot plate to form a resist underlayer film. The conditions for baking are appropriately selected from a baking temperature of 100° C. to 400° C. and a baking time of 0.3 minutes to 60 minutes. Preferably, the baking temperature is 120° C. to 350° C. and the baking time is 0.5 minutes to 30 minutes, and more preferably, the baking temperature is 150° C. to 300° C. and the baking time is 0.8 minutes to 10 minutes.

A film thickness of a resist underlayer film to be formed is, for example, within the range of 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm). In a case where the temperature during baking is lower than the above range, crosslinking becomes insufficient. To the contrary, when the temperature during the baking is higher than the above range, the resist underlayer film may be decomposed by heat.

### <Method for Manufacturing Patterned Substrate and Method for Manufacturing Semiconductor Device>

A method for manufacturing a patterned substrate includes the following steps. Usually, a photoresist layer is formed on a resist underlayer film. A photoresist formed by performing application and baking on the resist underlayer film by a method known per se is not particularly limited as long as it is sensitive to light used for exposure. Either a negative photoresist or a positive photoresist may be used. Examples of the photoresist include a positive photoresist formed of a novolac resin and 1,2-naphthoquinonediazide sulfonic acid ester, a chemically amplified photoresist formed of a binder having a group degradable by an acid to increase an alkali dissolution rate and a photoacid generator, a chemically amplified photoresist formed of a low-molecular-weight compound degradable by an acid to increase an alkali dissolution rate of the photoresist, an alkali-soluble binder, and a photoacid generator, a chemically amplified photoresist formed of a binder having a group degradable by an acid to increase an alkali dissolution rate, a low-molecular-weight compound degradable by an acid to increase an alkali dissolution rate of the photoresist, and a photoacid generator, and a resist containing metal elements. Examples thereof include V146G (trade name) manufactured by JSR Corporation, APEX-E (trade name) manufactured by Shipley Company L.L.C, PAR710 (trade name) manufactured by Sumitomo Chemical Co., Ltd., and AR2772 and SEPR430 (trade name) manufactured by Shin-Etsu Chemical Co., Ltd. In addition, examples thereof include a fluorine-containing atomic polymer-based photoresist as described in Proc. SPIE, Vol. 3999, 330-334 (2000), Proc. SPIE, Vol. 3999, 357-364 (2000), and Proc. SPIE, Vol. 3999, 365-374 (2000).

In addition, the resist compositions described in WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, JP 2011-253185 A, and the like, the so-called resist compositions such as a radiation-sensitive resin composition and a high-resolution patterning composition based on an organometallic solution, and a metal-containing resist composition may be used, but are not limited thereto.

Examples of the resist composition include the following compositions.

An active ray-sensitive or radiation-sensitive resin composition containing: a resin A having a repeating unit having an acid-decomposable group in which a polar group is protected by a protecting group that is removed by an action of an acid; and a compound represented by General Formula (21).

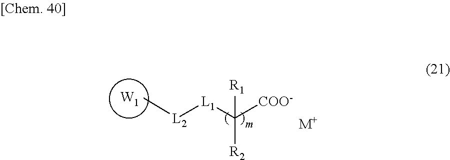

In General Formula (21), m represents an integer of 1 to 6.

R₁ and R₂ each independently represent a fluorine atom or a perfluoroalkyl group.

L₁ represents-O—, —S—, —COO—, —SO₂—, or —SO₃—.

L₂ represents an optionally substituted alkylene group or a single bond.

W₁ represents an optionally substituted cyclic organic group.

M⁺ represents a cation.

A metal-containing film-forming composition for extreme ultraviolet ray or

electron beam lithography, containing: a solvent and a compound having a metal-oxygen covalent bond, in which the metal elements constituting the compound belong to the third to seventh periods of Groups 3 to 15 of the periodic table.

A radiation-sensitive resin composition containing: an acid generator and a polymer having a first structural unit represented by the following Formula (31) and a second structural unit having an acid-dissociable group represented by the following Formula (32).

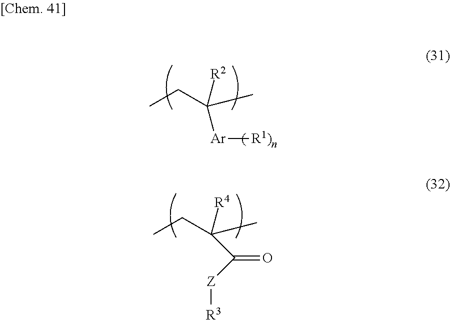

(In Formula (31), Ar is a group obtained by removing (n+1) hydrogen atoms from arene having 6 to 20 carbon atoms. R¹ is a hydroxy group, a sulfanyl group, or a monovalent organic group having 1 to 20 carbon atoms. n is an integer of 0 to 11. When n is 2 or more, a plurality of R¹'s are the same as or different from each other. R² is a hydrogen atom, a fluorine atom, a methyl group, or a trifluoromethyl group. In Formula (32), R³ is a monovalent group having 1 to 20 carbon atoms with the acid-dissociable group. Z is a single bond, an oxygen atom, or a sulfur atom. R⁴ is a hydrogen atom, a fluorine atom, a methyl group, or a trifluoromethyl group.)

A resist composition containing: an acid generator and a resin (A1) having a structural unit having a cyclic carbonic acid ester structure, a structural unit represented by the following formula, and a structural unit having an acid-unstable group.

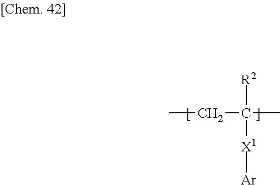

[In the formula,

R² represents an alkyl group having 1 to 6 carbon atoms which may have a halogen atom, a hydrogen atom, or a halogen atom, X¹ represents a single bond, —CO—O—*, or —CO—NR⁴—*, * represents a bond with —Ar, R⁴ represents a hydrogen atom or an alkyl group having 1 to 4 carbon atoms, and Ar represents an aromatic hydrocarbon group having 6 to 20 carbon atoms which may have one or more groups selected from the group consisting of a hydroxy group and a carboxyl group.]

Examples of the resist film include the following.

A resist film containing a base resin having a repeating unit represented by the following Formula (a1) and/or a repeating unit represented by the following Formula (a2), and a repeating unit that generates an acid bonded to a polymer main chain by exposure.

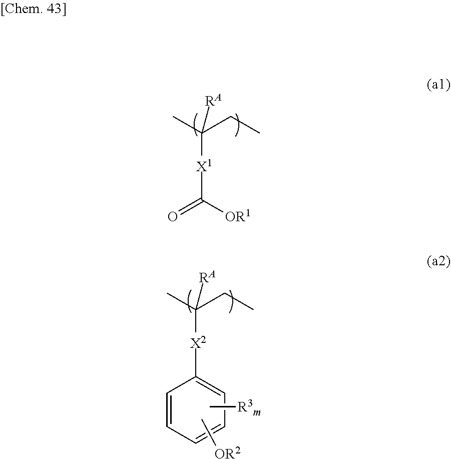

(In Formula (a1) and Formula (a2), R^{A}'s are each independently a hydrogen atom or a methyl group. R¹ and R² are each independently a tertiary alkyl group having 4 to 6 carbon atoms. R³'s each independently represent a fluorine atom or a methyl group. m is an integer of 0 to 4. X¹ is a single bond, a phenylene group or a naphthylene group, or a linking group having 1 to 12 carbon atoms containing at least one member selected from an ester bond, a lactone ring, a phenylene group, and a naphthylene group. X² is a single bond, an ester bond, or an amide bond.) Examples of a resist material include the following.

A resist material containing a polymer having a repeating unit represented by the following Formula (b1) or Formula (b2).

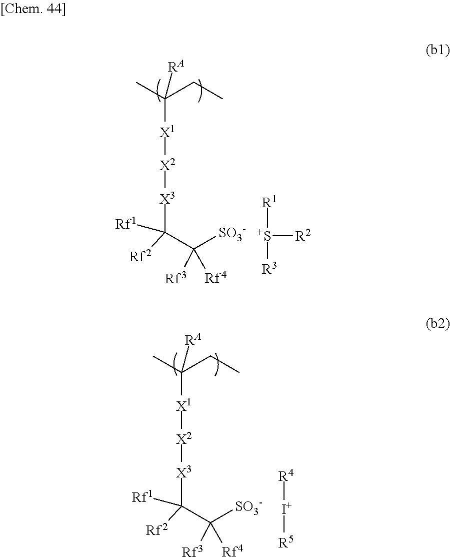

(In Formula (b1) and Formula (b2), R^{A} is a hydrogen atom or a methyl group. X¹ is a single bond or an ester group. X² is a linear, branched, or cyclic alkylene group having 1 to 12 carbon atoms or an arylene group having 6 to 10 carbon atoms, a part of a methylene group constituting the alkylene group may be substituted with an ether group, an ester group, or a lactone ring-containing group, and at least one hydrogen atom contained in X² is substituted with a bromine atom. X³ is a single bond, an ether group, an ester group, or a linear, branched, or cyclic alkylene group having 1 to 12 carbon atoms, and a part of a methylene group constituting the alkylene group may be substituted with an ether group or an ester group. Rf¹ to Rf⁴ are each independently a hydrogen atom, a fluorine atom, or a trifluoromethyl group, and at least one of Rf¹ to Rf⁴ is a fluorine atom or a trifluoromethyl group. In addition, Rf¹ and Rf² may be combined to form a carbonyl group. R¹ to R⁵ each independently represent a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, some or all of the hydrogen atoms in these groups may be substituted with a hydroxy group, a carboxy group, a halogen atom, an oxo group, a cyano group, an amide group, a nitro group, a sultone group, a sulfone group, or a sulfonium salt-containing group, and a part of a methylene group constituting each of these groups may be substituted with an ether group, an ester group, a carbonyl group, a carbonate group, or a sulfonic acid ester group. In addition, R¹ and R² may be bonded to form a ring together with a sulfur atom to which they are bonded.)

A resist material containing a base resin containing a polymer having a repeating unit represented by the following Formula (a).

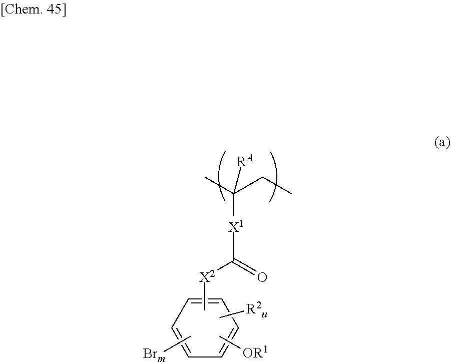

(In Formula (a), R^{A} is a hydrogen atom or a methyl group. R¹ is a hydrogen atom or an acid-unstable group. R² is a linear, branched, or cyclic alkyl group having 1 to 6 carbon atoms or a halogen atom other than bromine. X¹ is a single bond or a phenylene group, or a linear, branched, or cyclic alkylene group having 1 to 12 carbon atoms which may contain an ester group or a lactone ring. X² is —O—, —O—CH₂—, or —NH—. m is an integer of 1 to 4. n is an integer of 0 to 3.)

A resist composition which generates an acid by exposure and has solubility in a developer that is changed by an action of the acid, the resist composition containing:
a base component (A) having solubility in a developer that is changed by an action of an acid; and a fluorine additive component (F) exhibiting decomposability in an alkaline developer,
in which the fluorine additive component (F) contains a fluororesin component (F1) having a structural unit (f1) containing a base-dissociable group and a structural unit (f2) containing a group represented by the following General Formula (f2-r-1).

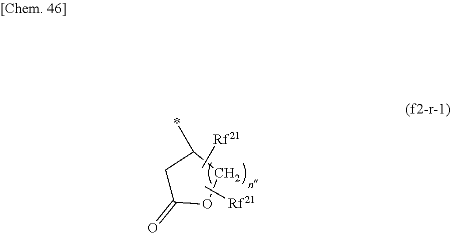

[In Formula (f2-r-1), Rf²¹'s each independently represent a hydrogen atom, an alkyl group, an alkoxy group, a hydroxy group, a hydroxyalkyl group, or a cyano group. n″ is an integer of 0 to 2. * represents a bond.]

The structural unit (f1) includes a structural unit represented by the following General Formula (f1-1) or a structural unit represented by the following General Formula (f1-2).

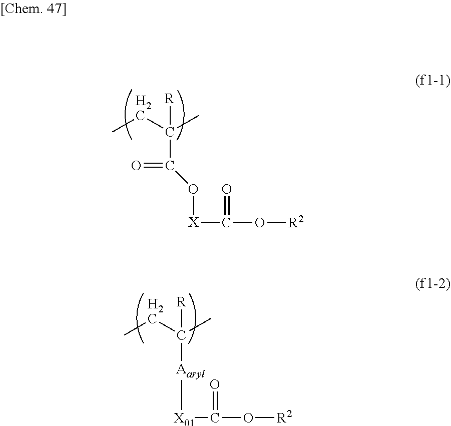

[In Formulas (f1-1) and (f1-2), R's are each independently a hydrogen atom, an alkyl group having 1 to 5 carbon atoms, or a halogenated alkyl group having 1 to 5 carbon atoms. X is a divalent linking group having no acid-dissociable site. A_{aryl} is an optionally substituted divalent aromatic cyclic group. X₀₁ is a single bond or a divalent linking group. R²'s are each independently an organic group having a fluorine atom.]

Examples of the coating, the coating solution, and the coating composition include the following.

A coating containing a metal oxo-hydroxo network having an organic ligand by a metal carbon bond and/or a metal carboxylate bond.

### Inorganic Oxo/Hydroxo-Based Composition.

A coating solution containing: an organic solvent; a first organometallic composition represented by Formula R_{z}SnO_{(2-(z/2)-(x/2))}(OH)ₓ (where 0<z≤2 and 0<(z+x)≤4), Formula R′ₙSnX₄₋ₙ (where n=1 or 2), or a mixture thereof, where R and R′ are independently a hydrocarbyl group having 1 to 31 carbon atoms, and X is a ligand having a hydrolyzable bond to Sn or a combination thereof; and a hydrolyzable metal compound represented by MX′ᵥ (where M is a metal selected from Groups 2 to 16 of the periodic table of the elements, v=number of 2 to 6, and X′ is a ligand having a hydrolyzable M-X bond or a combination thereof).

A coating solution containing: an organic solvent; and a first organometallic composition represented by Formula RSnO_{(3/2-x/2)}(OH)ₓ (in the formula, 0<x<3), in which about 0.0025 M to about 1.5 M tin is contained in the solution, R is an alkyl group or cycloalkyl group having 3 to 31 carbon atoms, and the alkyl group or cycloalkyl group is bonded to tin at a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

The exposure is performed through a mask (reticle) for forming a predetermined pattern, and for example, an i-line, a KrF energy laser, an ArF energy laser, an extreme ultraviolet ray (EUV), or an electron beam (EB) is used, but the resist underlayer film-forming composition of the present application is preferably applied for electron beam (EB) or extreme ultraviolet ray (EUV) exposure, and more preferably for extreme ultraviolet ray (EUV) exposure. In the development, an alkaline developer is used, and a development temperature and a development time are appropriately selected from 5° C. to 50° C. and 10 seconds to 300 seconds, respectively. As the alkaline developer, for example, aqueous solutions of alkalis, for example, inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butyl amine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, and cyclic amines such as pyrrole and piperidine, may be used. Furthermore, an appropriate amount of alcohols such as isopropyl alcohol and a surfactant such as a nonionic surfactant may be added to the aqueous solution of alkalis. Of these, a preferred developer is a quaternary ammonium salt and more preferably tetramethylammonium hydroxide and choline. Furthermore, a surfactant or the like may be added to the developer. Instead of the alkaline developer, a method of performing development with an organic solvent such as butyl acetate and developing a portion where an alkali dissolution rate of the photoresist is not increased may also be used. Through the above steps, a substrate on which the resist is patterned can be manufactured.

Next, the resist underlayer film is dry-etched using the formed resist pattern as a mask. At that time, when the inorganic film is formed on the surface of the used semiconductor substrate, the surface of the inorganic film is allowed to be exposed. When the inorganic film is not formed on the surface of the used semiconductor substrate, the surface of the semiconductor substrate is allowed to be exposed. Thereafter, the semiconductor device may be manufactured through a step of processing the substrate by a method known per se (a dry etching method or the like).

### EXAMPLES

Next, the present invention will be described in more detail with reference to Examples, but the present invention is not limited thereto.

The weight average molecular weight of polymers shown in the following Synthesis Example 1, Synthesis Example 2, Synthesis Example 3, Synthesis Example 4, and Comparative Synthesis Example 1 of the present specification is the result of the measurement by gel permeation chromatography (hereinafter, abbreviated as GPC). For the measurement, a GPC apparatus manufactured by Tosoh Corporation was used, and the measurement conditions and the like were as follows.
GPC column: Shodex KF803L, Shodex KF802, Shodex KF801 [registered trademark] (Showa Denko K. K.)
Column temperature: 40° C.
Solvent: tetrahydrofuran (THF)
Flow rate: 1.0 ml/min
Standard sample: polystyrene (manufactured by Tosoh Corporation)

### Synthesis Example 1

5.00 g of monoallyl diglycidyl isocyanurate (manufactured by Shikoku Chemicals Corporation), 3.01 g of 3,3′-dithiodipropionic acid (manufactured by Tokyo Chemical Industry Co., Ltd., trade name: DTDPA), 0.59 g of morpholine (manufactured by Tokyo Chemical Industry Co., Ltd.), and 0.20 g of tetrabutylphosphonium bromide (manufactured by ACROSS Corporation) were added to 12.56 g of propylene glycol monomethyl ether and dissolved. The inside of a reaction vessel was replaced with nitrogen, and then a reaction was allowed to proceed at 80° C. for 24 hours, thereby obtaining a polymer solution. The polymer solution did not cause cloudiness or the like even when cooled to room temperature, and had excellent solubility in propylene glycol monomethyl ether. GPC analysis showed that the polymer in the yielded solution had a weight average molecular weight of 5,000 in terms of standard polystyrene. The structure present in the polymer obtained in the present synthesis example is shown in the following formula.

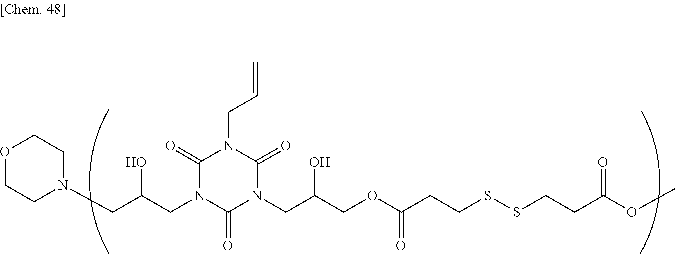

### Synthesis Example 2

5.00 g of monoallyl diglycidyl isocyanurate (manufactured by Shikoku Chemicals Corporation), 3.18 g of 3,3′-dithiodipropionic acid (manufactured by Tokyo Chemical Industry Co., Ltd., trade name: DTDPA), 0.47 g of 4-dimethylaminobenzoic acid (manufactured by Tokyo Chemical Industry Co., Ltd.), and 0.20 g of tetrabutylphosphonium bromide (manufactured by ACROSS Corporation) were added to 13.29 g of propylene glycol monomethyl ether and dissolved. The inside of a reaction vessel was replaced with nitrogen, and then a reaction was allowed to proceed at 80° C. for 24 hours, thereby obtaining a polymer solution. The polymer solution did not cause cloudiness or the like even when cooled to room temperature, and had excellent solubility in propylene glycol monomethyl ether. GPC analysis showed that the polymer in the yielded solution had a weight average molecular weight of 6,000 in terms of standard polystyrene. The structure present in the polymer obtained in the present synthesis example is shown in the following formula.

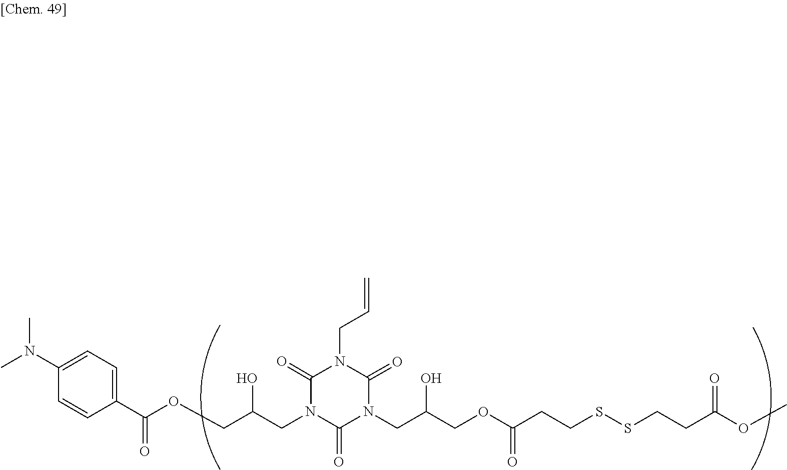

### Synthesis Example 3

20.00 g of monoallyl diglycidyl isocyanurate (manufactured by Shikoku Chemicals Corporation), 11.16 g of diethyl barbital (manufactured by HACHIDAI PHARMACEUTICAL CO., LTD.), 1.86 g of morpholine (manufactured by Tokyo Chemical Industry Co., Ltd.), and 0.83 g of tetrabutylphosphonium bromide (manufactured by ACROSS Corporation) were added to 50.78 g of propylene glycol monomethyl ether and dissolved. The inside of a reaction vessel was replaced with nitrogen, and then a reaction was allowed to proceed at 105° C. for 24 hours, thereby obtaining a polymer solution. The polymer solution did not cause cloudiness or the like even when cooled to room temperature, and had excellent solubility in propylene glycol monomethyl ether. GPC analysis showed that the polymer in the yielded solution had a weight average molecular weight of 5,000 in terms of standard polystyrene. The structure present in the polymer obtained in the present synthesis example is shown in the following formula.

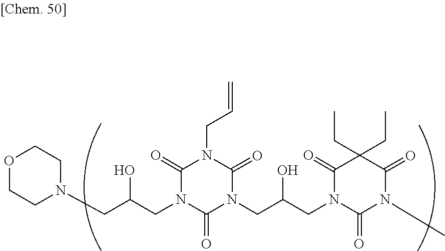

### Synthesis Example 4

5.00 g of monoallyl diglycidyl isocyanurate (manufactured by Shikoku Chemicals Corporation), 2.80 g of diethyl barbital (manufactured by HACHIDAI PHARMACEUTICAL CO., LTD.), 0.89 g of 4-dimethylaminobenzoic acid (manufactured by Tokyo Chemical Industry Co., Ltd.), and 0.20 g of tetrabutylphosphonium bromide (manufactured by ACROSS Corporation) were added to 13.34 g of propylene glycol monomethyl ether and dissolved. The inside of a reaction vessel was replaced with nitrogen, and then a reaction was allowed to proceed at 105° C. for 24 hours, thereby obtaining a polymer solution. The polymer solution did not cause cloudiness or the like even when cooled to room temperature, and had excellent solubility in propylene glycol monomethyl ether. GPC analysis showed that the polymer in the yielded solution had a weight average molecular weight of 6,000 in terms of standard polystyrene. The structure present in the polymer obtained in the present synthesis example is shown in the following formula.

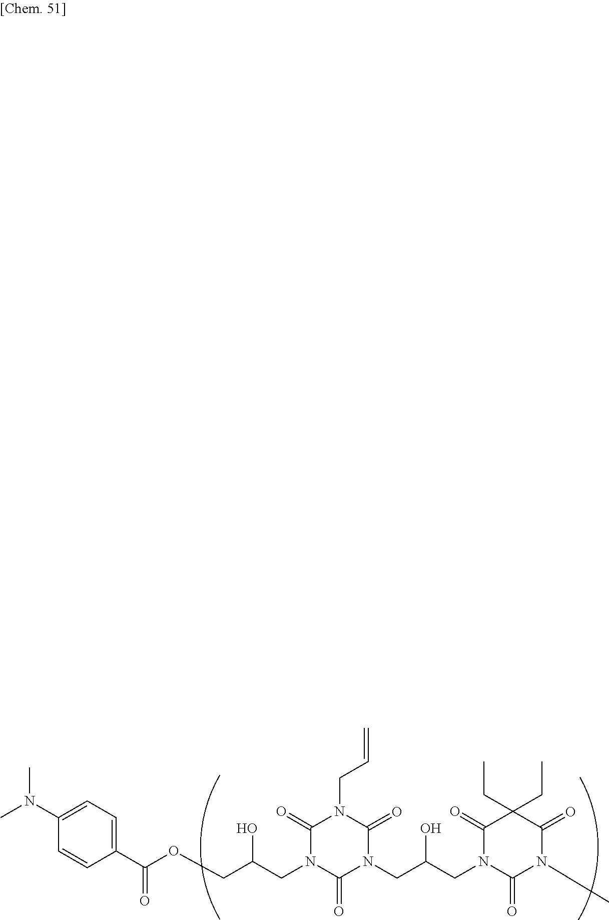

### Comparative Synthesis Example 1

3.00 g of monoallyl diglycidyl isocyanurate (manufactured by Shikoku Chemicals Corporation), 1.91 g of 3,3′-dithiodipropionic acid (manufactured by Sakai Chemical Industry Co., Ltd., trade name: DTDPA), 0.57 g of adamantane carboxylic acid (manufactured by Tokyo Chemical Industry Co., Ltd.), and 0.14 g of tetrabutylphosphonium bromide (manufactured by ACROSS Corporation) were added to 6.87 g of propylene glycol monomethyl ether and dissolved. The inside of a reaction vessel was replaced with nitrogen, and then a reaction was allowed to proceed at 80° C. for 24 hours, thereby obtaining a polymer solution. The polymer solution did not cause cloudiness or the like even when cooled to room temperature, and had excellent solubility in propylene glycol monomethyl ether. GPC analysis showed that the polymer in the yielded solution had a weight average molecular weight of 5,000 in terms of standard polystyrene. The structure present in the polymer obtained in the present synthesis example is shown in the following formula.

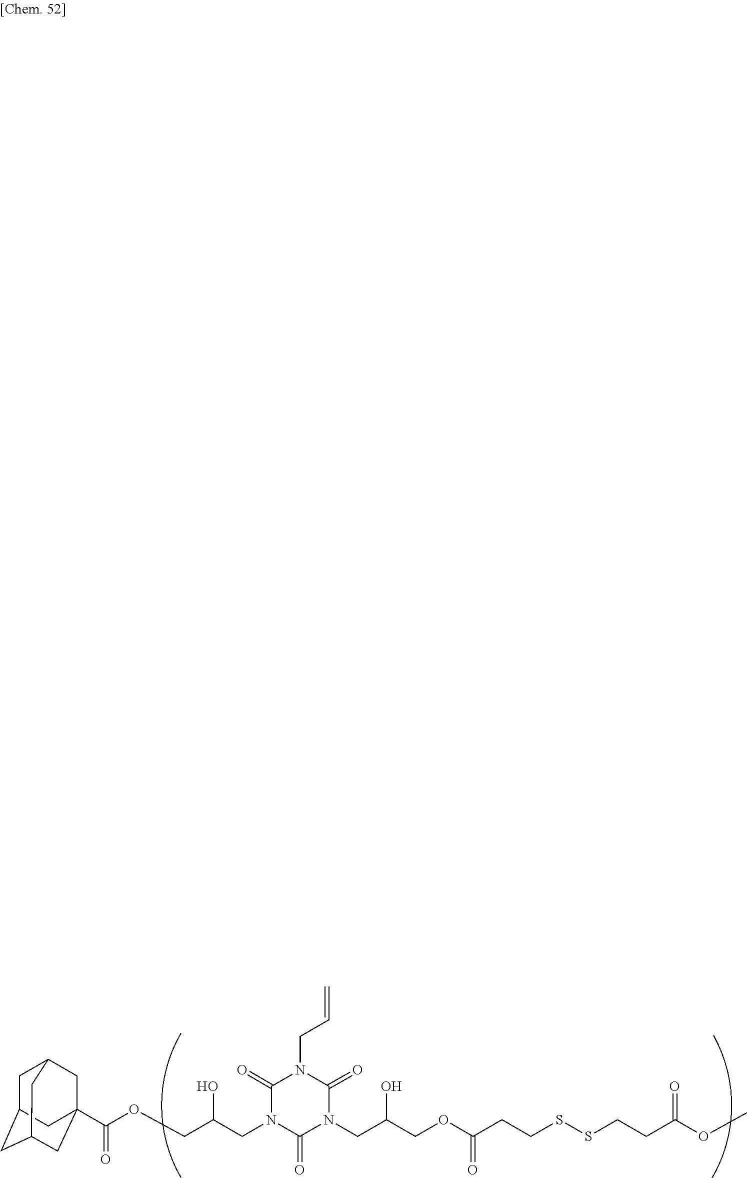

### Example 1

To 10.00 g (solid content: 20.0% by weight) of the polymer solution obtained in Synthesis Example 1 was added 0.27 g (100% by mole relative to the terminal of the polymer) of p-toluenesulfonic acid, and the resultant mixture was stirred at room temperature for 24 hours. By the stirring for 24 hours, p-toluenesulfonic acid was coordinated to morpholine in the polymer. Thereafter, the solution was reprecipitated from 2-propanol to remove uncoordinated p-toluenesulfonic acid. The removal was confirmed by GPC. The obtained polymer solid was dissolved in propylene glycol monomethyl ether to form a solution. The structure of the polymer present in the polymer solution obtained in the present example is shown in the following formula.

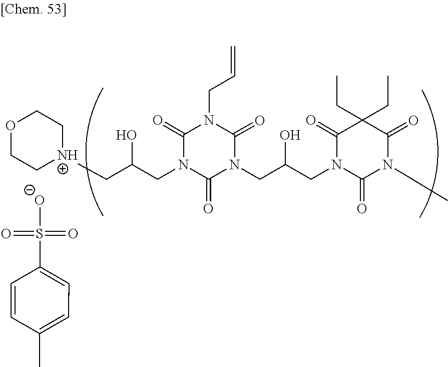

### Example 2

To 0.43 g (solid content: 16.4% by weight) of the polymer solution obtained in Example 1, 0.02 g of tetramethoxymethyl glycoluril (manufactured by Nihon Cytec Industries Inc.), 44.5 g of propylene glycol monomethyl ether, and 4.99 g of propylene glycol monomethyl ether acetate were added and dissolved. Thereafter, the resultant solution was filtered using a polyethylene microfilter having a pore diameter of 0.05 μm to obtain a resist underlayer film-forming composition for lithography.

### Example 3

To 10.00 g (solid content: 20.0% by weight) of the polymer solution obtained in Synthesis Example 2 was added 0.27 g (100% by mole relative to the terminal of the polymer) of p-toluenesulfonic acid, and the resultant mixture was stirred at room temperature for 24 hours. By the stirring for 24 hours, p-toluenesulfonic acid was coordinated to morpholine in the polymer. Thereafter, the solution was reprecipitated from 2-propanol to remove uncoordinated p-toluenesulfonic acid. The removal was confirmed by GPC. The obtained polymer solid was dissolved in propylene glycol monomethyl ether to form a solution. The structure of the polymer present in the polymer solution obtained in the present example is shown in the following formula.

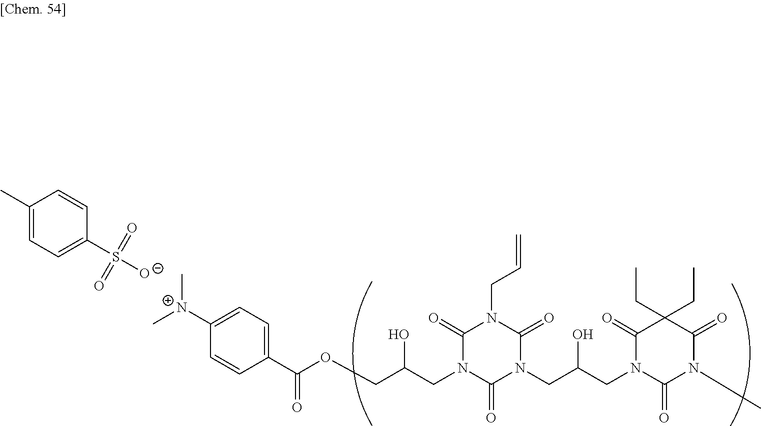

### Example 4

To 0.43 g (solid content: 16.4% by weight) of the polymer solution obtained in Example 3, 0.02 g of tetramethoxymethyl glycoluril (manufactured by Nihon Cytec Industries Inc.), 44.5 g of propylene glycol monomethyl ether, and 4.99 g of propylene glycol monomethyl ether acetate were added and dissolved. Thereafter, the resultant solution was filtered using a polyethylene microfilter having a pore diameter of 0.05 μm to obtain a resist underlayer film-forming composition for lithography.

### Example 5

To 0.48 g (solid content: 20.0% by weight) of the polymer solution obtained in Synthesis Example 3, 0.02 g of tetramethoxymethyl glycoluril (manufactured by Nihon Cytec Industries Inc.), 0.02 g of p-toluenesulfonic acid (100% by mole relative to the terminal of the polymer), 44.4 g of propylene glycol monomethyl ether, and 4.99 g of propylene glycol monomethyl ether acetate were added and dissolved. Thereafter, the resultant solution was filtered using a polyethylene microfilter having a pore diameter of 0.05 μm to obtain a resist underlayer film-forming composition for lithography.

### Example 6

To 0.48 g (solid content: 20.0% by weight) of the polymer solution obtained in Synthesis Example 4, 0.02 g of tetramethoxymethyl glycoluril (manufactured by Nihon Cytec Industries Inc.), 0.02 g of p-toluenesulfonic acid (100% by mole relative to the terminal of the polymer), 44.4 g of propylene glycol monomethyl ether, and 4.99 g of propylene glycol monomethyl ether acetate were added and dissolved. Thereafter, the resultant solution was filtered using a polyethylene microfilter having a pore diameter of 0.05 μm to obtain a resist underlayer film-forming composition for lithography.

### Comparative Example 1

To 10.00 g (solid content: 20.0% by weight) of the polymer solution obtained in Comparative Synthesis Example 1 was added 0.27 g (100% by mole relative to the terminal of the polymer) of p-toluenesulfonic acid, and the resultant solution was stirred at room temperature for 24 hours. Thereafter, the solution was reprecipitated from 2-propanol to remove uncoordinated p-toluenesulfonic acid. The removal was confirmed by GPC. The obtained polymer solid was dissolved in propylene glycol monomethyl ether to form a solution.

### Comparative Example 2

To 0.43 g (solid content: 16.4% by weight) of the polymer solution obtained in Comparative Example 1, 0.02 g of tetramethoxymethyl glycoluril (manufactured by Nihon Cytec Industries Inc.), 44.5 g of propylene glycol monomethyl ether, and 4.99 g of propylene glycol monomethyl ether acetate were added and dissolved. Thereafter, the resultant solution was filtered using a polyethylene microfilter having a pore diameter of 0.05 μm to obtain a resist underlayer film-forming composition for lithography.

### Comparative Example 3

To 0.47 g (solid content: 20.0% by weight) of the polymer solution obtained in Comparative Synthesis Example 1, 0.02 g of tetramethoxymethyl glycoluril (manufactured by Nihon Cytec Industries Inc.), 0.003 g of pyridinium phenolsulfonic acid, 44.6 g of propylene glycol monomethyl ether, and 4.99 g of propylene glycol monomethyl ether acetate were added and dissolved. Thereafter, the resultant solution was filtered using a polyethylene microfilter having a pore diameter of 0.05 μm to obtain a resist underlayer film-forming composition for lithography.

### [Elution Test in Photoresist Solvent]

Each of the resist underlayer film-forming compositions of Example 2, Example 4, Example 5, Example 6, Comparative Example 2, and Comparative Example 3 was applied onto a silicon wafer as a semiconductor substrate using a spinner. The silicon wafer was placed on a hot plate and baked at 205° C. for 1 minute to form a resist underlayer film (thickness 5 nm). These resist underlayer films were immersed in ethyl lactate and propylene glycol monomethyl ether, which are solvents used for a photoresist. The film that provided a film thickness change of less than 1 Å was evaluated as good, and the film that provided a film thickness change of 1 Å or more was evaluated as poor. The results thereof are shown in Table 1.

TABLE 1

| | Elution test |
|---|---|
| Example 2 | Good |
| Example 4 | Good |
| Example 5 | Good |
| Example 6 | Good |
| Comparative Example 2 | Poor |
| Comparative Example 3 | Good |

The results suggested that, in Example 2 and Example 4, p-toluenesulfonic acid was coordinated to and supported on each of the polymers to form a salt. On the other hand, Comparative Example 2 suggests that p-toluenesulfonic acid was neither coordinated to nor supported on the polymer. In addition, in Examples 4 and 5, sufficient solvent resistance was exhibited even when p-toluenesulfonic acid was added during formulation.

### [Formation of Negative Resist Pattern by Electron Beam Drawing Apparatus]

Each of the resist underlayer film-forming compositions of Example 2, Example 4, Example 5, Example 6, and Comparative Example 3 was applied onto a silicon wafer using a spinner. The silicon wafer was baked on a hot plate at 205° C. for 60 seconds to obtain a resist underlayer film having a thickness of 5 nm. A positive resist solution for EUV (containing a methacrylic polymer) was spin-coated on the resist underlayer film, and heating was performed at 130° C. for 60 seconds, thereby forming an EUV resist film. The resist film was exposed under the predetermined conditions using an electron beam drawing apparatus (ELS-G130). After the exposure, bake (PEB) was performed at 100° C. for 60 seconds, cooling was performed on a cooling plate to room temperature, development was performed with an alkaline developer (2.38% TMAH), and then a 26 nm pillar pattern/resist pattern with a 52 nm pitch was formed. A scanning electron microscope (manufactured by Hitachi High-Technologies Corporation, CG4100) was used for measuring a length of the resist pattern. The photoresist pattern thus obtained was observed from the above and evaluated. In the formation of the resist pattern, a case where the pillar pattern was successfully formed was indicated as “good”, and a case where the pillar pattern was collapsed or peeled was indicated as “poor”. In addition, the exposure amounts required for forming the pillar patterns having a CD size of 26 nm were compared.

TABLE 2

| | Pillar pattern having CD size of 26 nm |
|---|---|
| Example 2 | Good |
| Example 4 | Good |
| Example 5 | Good |
| Example 6 | Good |
| Comparative Example 3 | Poor |

The results suggested that lithographic performance could be improved by supporting a thermal acid generator, which has conventionally used to promote a crosslinking reaction on a polymer.

### INDUSTRIAL APPLICABILITY

The resist underlayer film-forming composition according to the present invention can provide a composition for forming a resist underlayer film that can form a desired resist pattern, a method for manufacturing a substrate with a resist pattern using the resist underlayer film-forming composition, and a method for manufacturing a semiconductor device.

1. A resist underlayer film-forming composition comprising a solvent and a polymer that supports an acid compound at a terminal thereof.

2. The resist underlayer film-forming composition according to claim 1, wherein the acid compound is ionically bonded to a base present at a terminal of the polymer.

3. The resist underlayer film-forming composition according to claim 1 or 2, wherein
the terminal is represented by the following Formula (I): 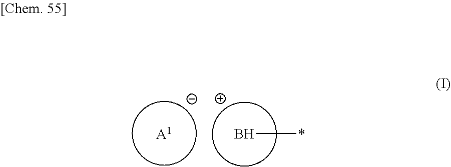
(in Formula (I), A¹ represents an acid compound, B represents a basic structure, and * is a binding site with a polymer residue).

4. The resist underlayer film-forming composition according to claim 3, wherein B contains a nitrogen atom.

5. The resist underlayer film-forming composition according to claim 3 or 4, wherein
B is R¹R²R³N,
R¹ and R² each independently represent an optionally substituted linear or branched saturated or unsaturated aliphatic hydrocarbon group,
R¹ and R² may form a ring with a heteroatom or without a heteroatom,
R³ represents an optionally substituted aromatic group, or an optionally substituted linear or branched saturated or unsaturated aliphatic hydrocarbon group, and
when R¹ and R² do not form a ring, R³ is an optionally substituted aromatic group.

6. The resist underlayer film-forming composition according to claim 3 or 4, wherein
B is a base represented by
R¹R²R³N [Chem. 56]
[in the formula,
R¹ and R² each independently represent an optionally substituted linear or branched saturated or unsaturated aliphatic hydrocarbon group, and
R³ represents an optionally substituted aromatic group], or
the following Formula (II): 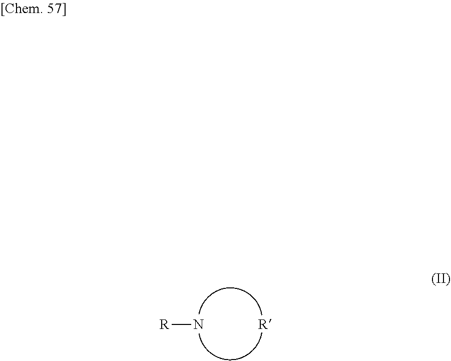
[in Formula (II),
R is a hydrogen atom, a nitro group, a cyano group, an amino group, a carboxyl group, a halogen atom, an alkoxy group having 1 to 10 carbon atoms, an alkyl group having 1 to 10 carbon atoms, an alkenyl group having 2 to 10 carbon atoms, an aryl group having 6 to 40 carbon atoms, an organic group containing an ether bond, an organic group containing a ketone bond, an organic group containing an ester bond, or a combination thereof,
R′ is
—(R^{a})ₙ—X—(R^{b})ₘ—, [Chem. 58]
R^{a} and R^{b} each independently represent an optionally substituted alkyl,
X is O, S, or SO₂, and
n and m are each independently 2, 3, 4, 5, or 6].

7. The resist underlayer film-forming composition according to claim 6, wherein
R³ represents an optionally substituted phenyl, naphthyl, anthracenyl, or phenanthrenyl group,
R is a hydrogen atom, a methyl group, an ethyl group, an allyl group, or a cyanomethyl group, and
R′ is a base represented by
—(CH₂)ₙ—O—(CH₂)ₘ—. [Chem. 59]

8. The resist underlayer film-forming composition according to any one of claims 3 to 7, wherein
A¹ is represented by the following formula:
[Chem. 60]
(A-SO₃)— (I I I)
(in Formula (III), A is an optionally substituted linear, branched, or cyclic saturated or unsaturated aliphatic hydrocarbon group, an aryl group which may be substituted with a group other than a carboxyl group, or an optionally substituted heteroaryl group).

9. The resist underlayer film-forming composition according to any one of claims 1 to 8, wherein
the polymer is a polymer having a repeating unit structure represented by the following Formula (1): 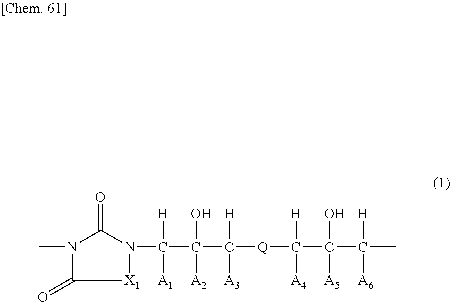
[in the formula, each of A₁, A₂, A₃, A₄, A₅, and A₆ represents a hydrogen atom, a methyl group, or an ethyl group, X₁ represents Formula (2), Formula (3), Formula (4), or Formula (0): 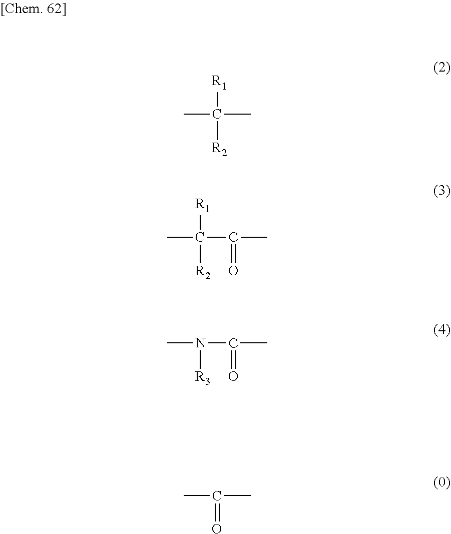
(in the formula, each of R₁ and R₂ represents a hydrogen atom, a halogen atom, an alkyl group having 1 to 6 carbon atoms, an alkenyl group having 3 to 6 carbon atoms, a benzyl group, or a phenyl group, in which the alkyl group having 1 to 6 carbon atoms, the alkenyl group having 3 to 6 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 6 carbon atoms, R₁ and R₂ may be bonded to each other to form a ring having 3 to 6 carbon atoms, and R₃ represents a halogen atom, an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms), and Q represents Formula (5) or Formula (6): 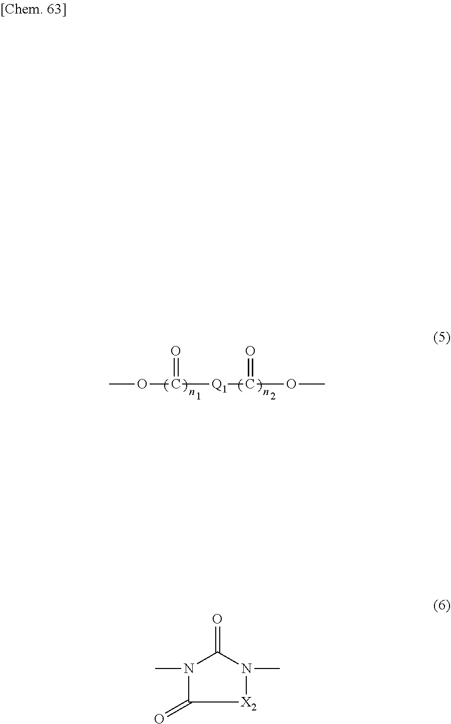
(in the formula, Q₁ represents an alkylene group having 1 to 10 carbon atoms, a phenylene group, a naphthylene group, or an anthrylene group, in which each of the alkylene group, the phenylene group, the naphthylene group, and the anthrylene group may be substituted with an alkyl group having 1 to 6 carbon atoms, a carbonyloxyalkyl group having 2 to 7 carbon atoms, a halogen atom, an alkoxy group having 1 to 6 carbon atoms, a phenyl group, a nitro group, a cyano group, a hydroxy group, an alkylthio group having 1 to 6 carbon atoms, a group having a disulfide group, a carboxyl group, or a combination thereof, and the alkylene group may be interrupted by a disulfide bond, each of n₁ and n₂ represents a number of 0 or 1, and X₂ represents Formula (2), Formula (3), or Formula (0))].

10. The resist underlayer film-forming composition according to any one of claims 1 to 9, further comprising a crosslinking agent.

11. The resist underlayer film-forming composition according to any one of claims 1 to 10, further comprising an acid generator.

12. A resist underlayer film which is a baked product of a coating film formed of the resist underlayer film-forming composition according to claims 1 to 11.

13. A method for manufacturing a patterned substrate, the method comprising:
applying the resist underlayer film-forming composition according to any one of claims 1 to 11 onto a semiconductor substrate and baking the resist underlayer film-forming composition to form a resist underlayer film;
applying a resist onto the resist underlayer film and baking the resist to form a resist film;
exposing the semiconductor substrate coated with the resist underlayer film and the resist; and
developing the exposed resist film and performing patterning.

14. A method for manufacturing a semiconductor device, the method comprising:
forming a resist underlayer film of the resist underlayer film-forming composition according to any one of claims 1 to 11 on a semiconductor substrate;
forming a resist film on the resist underlayer film;
forming a resist pattern by irradiating the resist film with a light or electron beam and then developing the resist film;
forming a patterned resist underlayer film by etching the resist underlayer film through the formed resist pattern; and
processing the semiconductor substrate by the patterned resist underlayer film.
